(19) United States
(12) Patent Application Publication
(10) Pub. No.: US 2024/0194830 A1
(43) Pub. Date: Jun. 13, 2024

(54) SEMICONDUCTOR LIGHT-EMITTING ELEMENT AND METHOD OF MANUFACTURING SEMICONDUCTOR LIGHT-EMITTING ELEMENT

(71) Applicant: NIKKISO CO., LTD., Tokyo (JP)

(72) Inventors: Noritaka NIWA, Ishikawa (JP); Tetsuhiko INAZU, Ishikawa (JP)

(21) Appl. No.: 18/533,729

(22) Filed: Dec. 8, 2023

(30) Foreign Application Priority Data
Dec. 8, 2022 (JP) 2022-196624

(51) Int. Cl. H01L 33/38; H01L 33/00; H01L 33/24

(52) U.S. Cl. CPC H01L 33/382; H01L 33/0075; H01L 33/24

(57) ABSTRACT

A semiconductor light-emitting element includes a contact electrode in contact with an upper surface of a semiconductor layer, a protective layer covering the contact electrode, and a pad electrode provided on the protective layer. The contact electrode includes a first inclined portion in which an upper surface of the contact electrode is inclined such that the thickness of the contact electrode decreases toward an edge of the contact electrode. The width of the first inclined portion in a direction in which the edge of the contact electrode extends and in a predetermined direction orthogonal to a thickness direction of the contact electrode is 10 times or more the thickness of a portion of the contact electrode that is different from the first inclined portion.

### RELATED APPLICATION

Priority is claimed to Japanese Patent Application No. 2022-196624, filed on Dec. 8, 2022, the entire content of which is incorporated herein by reference.

### BACKGROUND

### 1. Field of the Invention

The present disclosure relates to a semiconductor light-emitting element and a method of manufacturing a semiconductor light-emitting element.

### 2. Description of the Related Art

A semiconductor light-emitting element includes an n-type semiconductor layer, an active layer, and a p-type semiconductor layer stacked on a substrate. An n-side electrode is provided on the n-type semiconductor layer, and a p-side electrode is provided on the p-type semiconductor layer. A protective layer made of a dielectric material such as SiO₂ is provided on the surface of the semiconductor light-emitting element (see, for example, JP 2016-171141 A).

The dielectric protective layer covering the electrode of the semiconductor light-emitting element may have a reduced film thickness at a portion covering the edge of the electrode. In this case, the covering property of the dielectric protective layer is reduced in the portion where the film thickness decreases, and the reliability of the semiconductor light-emitting element may be affected.

### SUMMARY

The present disclosure addresses the issue described above, and a purpose thereof is to provide a technology for improving the reliability of a semiconductor light-emitting element.

A semiconductor light-emitting element according to an aspect of the present disclosure includes: an n-type semiconductor layer; an active layer provided on a first upper surface of the n-type semiconductor layer; a p-type semiconductor layer provided on the active layer; a contact electrode in contact with a second upper surface different from the first upper surface of the n-type semiconductor layer or in contact with an upper surface of the p-type semiconductor layer; a protective layer covering the n-type semiconductor layer, the active layer, the p-type semiconductor layer, and the contact electrode and made of a dielectric material; and a pad electrode provided on the protective layer. The contact electrode includes a first inclined portion in which an upper surface of the contact electrode is inclined such that the thickness of the contact electrode decreases toward an edge of the contact electrode. The width of the first inclined portion in a direction in which the edge of the contact electrode extends and in a predetermined direction orthogonal to a thickness direction of the contact electrode is 10 times or more the thickness of a portion of the contact electrode that is different from the first inclined portion.

Another aspect of the present disclosure relates to a method of manufacturing a semiconductor light-emitting element. This method includes: forming an active layer on an n-type semiconductor layer; forming a p-type semiconductor layer on the active layer; partially removing each of the p-type semiconductor layer and the active layer to expose an upper surface of the n-type semiconductor layer; forming an n-side contact electrode in contact with the upper surface of the n-type semiconductor layer; forming a p-side contact electrode in contact with the upper surface of the p-type semiconductor layer; forming a protective layer made of a dielectric material and covering the n-type semiconductor layer, the active layer, the p-type semiconductor layer, the n-side contact electrode, and the p-side contact electrode; partially removing the protective layer to form an n-side opening and a p-side opening; forming an n-side pad electrode overlapping the protective layer to close the n-side opening; and forming a p-side pad electrode overlapping the protective layer to close the p-side opening. At least one of the forming of the n-side contact electrode or the forming of the p-side contact electrode includes: forming a first resist having a first opening having an undercut shape; depositing an electrode layer in the first opening by using the first resist as a mask; and peeling and removing the first resist. The width of the undercut shape of the first resist in a direction in which an edge of the first opening of the first resist extends and in a predetermined direction orthogonal to a thickness direction of the first resist is equal to or more than 5 μm and equal to or less than 10 μm, and the height of the undercut shape of the first resist is equal to or less than 1 μm.

### BRIEF DESCRIPTION OF THE DRAWINGS

FIG. 1 is a cross sectional view schematically showing a configuration of a semiconductor light-emitting element according to a first embodiment;

FIG. 2 is a cross sectional view schematically showing an inclined structure of a contact electrode and a current diffusion layer according to the first embodiment;

FIG. 3 is a cross sectional view schematically showing a step of forming the contact electrode according to the first embodiment;

FIG. 4 is a cross sectional view schematically showing a step of forming the current diffusion layer according to the first embodiment;

FIG. 5 schematically shows a step of manufacturing the semiconductor light-emitting element according to the first embodiment;

FIG. 6 schematically shows a step of manufacturing the semiconductor light-emitting element according to the first embodiment;

FIG. 7 schematically shows a step of manufacturing the semiconductor light-emitting element according to the first embodiment;

FIG. 8 schematically shows a step of manufacturing the semiconductor light-emitting element according to the first embodiment;

FIG. 9 schematically shows a step of manufacturing the semiconductor light-emitting element according to the first embodiment;

FIG. 10 schematically shows a step of manufacturing the semiconductor light-emitting element according to the first embodiment;

FIG. 11 schematically shows a step of manufacturing the semiconductor light-emitting element according to the first embodiment;

FIG. 12 schematically shows a step of manufacturing the semiconductor light-emitting element according to the first embodiment;

FIG. 13 schematically shows a step of manufacturing the semiconductor light-emitting element according to the first embodiment;

FIG. 14 is a cross sectional view schematically showing a configuration of a semiconductor light-emitting element according to a second embodiment;

FIG. 15 is a cross sectional view schematically showing an inclined structure of a contact electrode and a current diffusion layer according to the second embodiment; and

FIG. 16 is a cross sectional view schematically showing a step of forming the current diffusion layer according to the second embodiment.

### DETAILED DESCRIPTION

The invention will now be described by reference to the preferred embodiments. This does not intend to limit the scope of the present invention, but to exemplify the invention.

A description will be given of an embodiment of the present invention with reference to the drawings. The numerals are used in the description to denote the same elements and a duplicate description is omitted as appropriate. To facilitate the understanding, the relative dimensions of the constituting elements in the drawings do not necessarily mirror the relative dimensions in the light-emitting element.

The semiconductor light-emitting element according to the embodiments is configured to emit “deep ultraviolet light” having a central wavelength λ of about 360 nm or shorter and is a so-called deep ultraviolet-light emitting diode (DUV-LED) chip. To output deep ultraviolet light having such a wavelength, an aluminum gallium nitride (AlGaN)-based semiconductor material having a band gap approximately equal to or more than 3.4 eV is used. The embodiments particularly show a case of emitting deep ultraviolet light having a central wavelength λ of about 240 nm-320 nm.

In this specification, the term “AlGaN-based semiconductor material” refers to a semiconductor material containing at least aluminum nitride (AlN) and gallium nitride (GaN) and shall encompass a semiconductor material containing other materials such as indium nitride (InN). Therefore, “AlGaN-based semiconductor materials” as recited in this specification can be represented by a composition In_{1-x-y}AlₓGa_{y}N (0<x+y≤1, 0<x<1, 0<y<1). The AlGaN-based semiconductor material shall encompass AlGaN or InAlGaN. The “AlGaN-based semiconductor material” in this specification has a molar fraction of AlN and a molar fraction of GaN equal to or more than 1%, and, preferably, equal to or more than 5%, equal to or more than 10%, or equal to or more than 20%.

Those materials that do not contain AlN may be distinguished by referring to them as “GaN-based semiconductor materials”. “GaN-based semiconductor materials” encompass GaN and InGaN. Similarly, those materials that do not contain GaN may be distinguished by referring to them as “AlN-based semiconductor materials”. “AlN-based semiconductor materials” encompass AlN and InAlN.

### First Embodiment

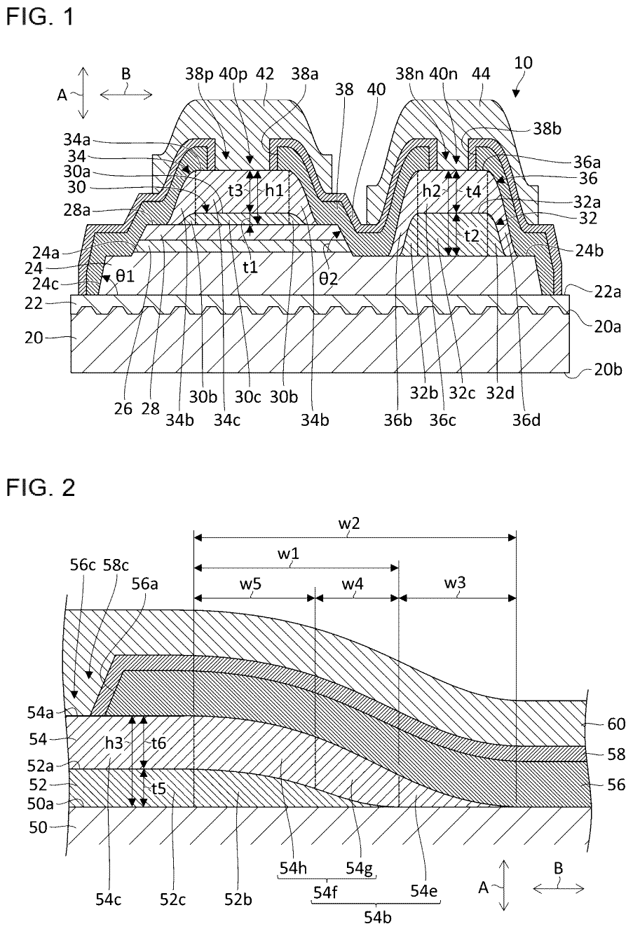

FIG. 1 is a cross sectional view schematically showing a configuration of a semiconductor light-emitting element 10 according to a first embodiment. The semiconductor light-emitting element 10 includes a substrate 20, a base layer 22, an n-type semiconductor layer 24, an active layer 26, a p-type semiconductor layer 28, a p-side contact electrode 30, an n-side contact electrode 32, a p-side current diffusion layer 34, an n-side current diffusion layer 36, a first protective layer 38, a second protective layer 40, a p-side pad electrode 42, and an n-side pad electrode 44.

Referring to FIG. 1, the direction indicated by the arrow A may be referred to as “vertical direction” or “thickness direction”. Further, the direction away from the substrate 20 may be defined as “upward”, and the direction toward the substrate 20 may be defined as “downward”. Referring to FIG. 1, the direction indicated by the arrow B may be referred to as “horizontal direction” or “width direction”. The direction indicated by the arrow B is, for example, a direction orthogonal to the thickness direction indicated by the arrow A, and is a direction orthogonal to the direction in which the edge of each component of the semiconductor light-emitting element 10 extends.

The substrate 20 includes a first principal surface 20a and a second principal surface 20b opposite to the first principal surface 20a. The first principal surface 20a is a crystal growth surface for growing the layers from the base layer 22 to the p-type semiconductor layer 28. The substrate 20 is made of a material having translucency for the deep ultraviolet light emitted by the semiconductor light-emitting element 10 and is made of, for example, sapphire (Al₂O₃). A fine concave-convex pattern having a submicron (1 μm or less) depth and pitch is formed on the first principal surface 20a. The substrate 20 like this is also called a patterned sapphire substrate (PSS). The second principal surface 20b is a light extraction substrate for extracting the deep ultraviolet light emitted by the active layer 26 outside. The substrate 20 may be made of AlN or made of AlGaN. The first principal surface 20a of the substrate 20 may be an ordinary substrate comprised of a flat surface that is not patterned.

The base layer 22 is provided on the first principal surface 20a of the substrate 20. The base layer 22 is a foundation layer (template layer) to form the n-type semiconductor layer 24. For example, the base layer 22 is an undoped AlN layer and is, specifically, an AlN layer gown at a high temperature-AlN (HT-AlN). The base layer 22 may further include an undoped AlGaN layer formed on the AlN layer. The base layer 22 may be comprised only of an undoped AlGaN layer when the substrate 20 is an AlN substrate or an AlGaN substrate. In other words, the base layer 22 includes at least one of an undoped AlN layer or an undoped AlGaN layer.

The n-type semiconductor layer 24 is provided on an upper surface 22a of the base layer 22. The n-type semiconductor layer 24 is made of an n-type AlGaN-based semiconductor material. For example, the n-type semiconductor layer 24 is doped with Si as an n-type impurity. The composition ratio of the n-type semiconductor layer 24 is selected to transmit the deep ultraviolet light emitted by the active layer 26. For example, the n-type semiconductor layer 24 is formed such that the molar fraction of AlN is equal to or more than 25%, and, preferably, equal to or more than 40% or equal to or more than 50%. The n-type semiconductor layer 24 has a band gap larger than the wavelength of the deep ultraviolet light emitted by the active layer 26. For example, the n-type semiconductor layer 24 is formed to have a band gap equal to or more than 4.3 eV. It is preferable to form the n-type semiconductor layer 24 such that the molar fraction of AlN is equal to or less than 80%, i.e., the band gap is equal to or less than 5.5 eV. It is more desired to form the n-type semiconductor layer 24 such that the molar fraction of AlN is equal to or less than 70% (i.e., the band gap is equal to or less than 5.2 eV). The n-type semiconductor layer 24 has a thickness equal to or more than 1 μm and equal to or less than 3 μm. For example, the n-type semiconductor layer 24 has a thickness of about 2 μm.

The n-type semiconductor layer 24 is formed such that the concentration of Si as the impurity is equal to or more than 1×10¹⁸/cm³ and equal to or less than 5×10¹⁹/cm³. It is preferred to form the n-type semiconductor layer 24 such that the Si concentration is equal to or more than 5×10¹⁸/cm³ and equal to or less than 3×10¹⁹/cm³ and, more preferably, equal to or more than 7×10¹⁸/cm³ and equal to or less than 2×10¹⁹/cm³. In one example, the Si concentration in the n-type semiconductor layer 24 is around 1×10¹⁹/cm³ and, more specifically, is in a range equal to or more than 8×10¹⁸/cm³ and equal to or less than 1.5×10¹⁹/cm³.

The n-type semiconductor layer 24 includes a first upper surface 24a, a second upper surface 24b, and a side surface 24c. The first upper surface 24a is where the active layer 26 is formed, and the second upper surface 24b is where the active layer 26 is not formed. The side surface 24c is sloped with respect to the first upper surface 24a at a first angle θ1. The first angle θ1 is larger than 40° (i.e., does not include 40°) and equal to or smaller than 70°.

The active layer 26 is provided on the first upper surface 24a of the n-type semiconductor layer 24. The active layer 26 is made of an AlGaN-based semiconductor material and has a double heterojunction structure by being sandwiched between the n-type semiconductor layer 24 and the p-type semiconductor layer 28. To output deep ultraviolet light having a wavelength equal to or less than 355 nm, the active layer 26 is formed to have a band gap equal to or more than 3.4 eV. For example, the AlN composition ratio of the active layer 26 is selected so as to output deep ultraviolet light having a wavelength equal to or less than 320 nm.

For example, the active layer 26 has a monolayer or multilayer quantum well structure and is comprised of a barrier layer made of an undoped AlGaN-based semiconductor material and a well layer made of an undoped AlGaN-based semiconductor material. The active layer 26 includes, for example, a first barrier layer in contact with the n-type semiconductor layer 24 and a first well layer provided on the first barrier layer. One or more pairs of the barrier layer and the well layer may be additionally provided between the first well layer and the p-type semiconductor layer 28. Each of the barrier layer and the well layer has a thickness equal to or more than 1 nm and equal to or less than 20 nm, and has, for example, a thickness equal to or more than 2 nm and equal to or less than 10 nm. The active layer 26 has a side surface (or a sloped surface) sloped at a second angle θ2. The second angle θ2 is smaller than the first angle θ1 and is equal to or smaller than 40°.

An electron blocking layer may further be provided between the active layer 26 and the p-type semiconductor layer 28. The electron blocking layer is made of an undoped AlGaN-based semiconductor material and is formed such that, for example, the molar fraction of AlN is equal to or more than 408, and, preferably, equal to or more than 50%. The electron blocking layer may be formed such that the molar fraction of AlN is equal to or more than 80% or may be made of an AlN-based semiconductor material that does not contain GaN. The electron blocking layer has a thickness equal to or more than 1 nm and equal to or less than 10 nm. For example, the electron blocking layer has a thickness equal to or more than 2 nm and equal to or less than 5 nm. The electron blocking layer has a side surface (or a sloped surface) sloped at a second angle θ2.

The p-type semiconductor layer 28 is formed on the active layer 26. The p-type semiconductor layer 28 is a p-type AlGaN-based semiconductor material layer or a p-type GaN-based semiconductor material layer. For example, the p-type semiconductor layer 28 is an AlGaN layer or a GaN layer doped with magnesium (Mg) as a p-type impurity. The p-type semiconductor layer 28 has, for example, a thickness equal to or more than 20 nm and equal to or less than 400 nm. The p-type semiconductor layer 28 has a side surface (or a sloped surface) sloped at a second angle θ2.

The p-type semiconductor layer 28 may be comprised of a plurality of layers. The p-type semiconductor layer 28 may include, for example, a p-type clad layer and a p-type contact layer. The p-type clad layer is a p-type AlGaN layer having a relatively high AlN ratio as compared with the p-type contact layer and is provided to be in contact with the active layer 26. The p-type contact layer is a p-type AlGaN layer or a p-type GaN layer having a relatively low AlN ratio as compared with the p-type clad layer. The p-type contact layer is provided on the p-type clad layer and is provided to be in contact with the p-side contact electrode 30. The p-type clad layer may include a p-type first clad layer and a p-side second clad layer.

The composition ratio of the p-type first clad layer is selected to transmit the deep ultraviolet light emitted by the active layer 26. For example, the p-type first clad layer is formed such that the molar fraction of AlN is equal to or more than 25%, and, preferably, equal to or more than 40% or equal to or more than 50%. The AlN ratio of the p-type first clad layer is, for example, similar to the AlN ratio of the n-type semiconductor layer 24 or larger than the AlN ratio of the n-type semiconductor layer 24. The AlN ratio of the p-type clad layer may be equal to or more than 70% or equal to or more than 80%. The p-type first clad layer has a thickness equal to or more than 10 nm and equal to or less than 100 nm. For example, the p-type first clad layer has a thickness equal to or more than 15 nm and equal to or less than 70 nm.

The p-type second clad layer is provided on the p-type first clad layer. The p-type second clad layer is a p-type AlGaN layer having a medium AlN ratio and has an AlN ratio lower than that of the p-type first clad layer and higher than that of the p-type contact layer. For example, the p-type second clad layer is formed such that the molar fraction of AlN is equal to or more than 25%, and, preferably, equal to or more than 40% or equal to or more than 50%. The AlN ratio of the p-type second clad layer is configured to be, for example, about +10% of the AlN ratio of the n-type semiconductor layer 24. The p-type second clad layer has a thickness equal to or more than 5 nm and equal to or less than 250 nm and has, for example, a thickness equal to or more than 10 nm and equal to or less than 150 nm. The p-type second clad layer may not be provided, and the p-type clad layer may be comprised only of the p-type first clad layer.

The p-type contact layer is a p-type AlGaN layer or a p-type GaN layer having a relatively low AlN ratio. The p-type contact layer is formed such that the AlN ratio is equal to or less than 20% in order to obtain proper ohmic contact with the p-side contact electrode 30. Preferably, the p-type contact layer is formed such that the AlN ratio is equal to or less than 10%, equal to or less than 5%, or 0%. In other words, the p-type contact layer may be made of a p-type GaN-based semiconductor material that does not substantially contain AlN. As a result, the p-type contact layer could absorb the deep ultraviolet light emitted by the active layer 26. It is preferred to form the p-type contact layer to be thin to reduce the quantity of absorption of the deep ultraviolet light emitted by the active layer 26. The p-type contact layer has a thickness equal to or more than 5 nm and equal to or less than 30 nm and has, for example, a thickness equal to or more than 10 nm and equal to or less than 20 nm.

The p-side contact electrode 30 is provided on an upper surface 28a of the p-type semiconductor layer 28. The p-side contact electrode 30 is in contact with the p-type semiconductor layer 28 (for example, the p-type contact layer). The p-side contact electrode 30 is made of a material that can be in ohmic contact with the p-type semiconductor layer 28 (for example, the p-type contact layer). The p-side contact electrode 30 includes, for example, an Rh layer in contact with the upper surface 28a of the p-type semiconductor layer 28. The p-side contact electrode 30 may be, for example, comprised only of the Rh layer. The thickness of the Rh layer included in the p-side contact electrode 30 is equal to or more than 50 nm and equal to or less than 200 nm and is, for example, equal to or more than 70 nm and equal to or less than 150 nm. In this case, a thickness t1 of the p-side contact electrode 30 may be equal to or more than 0.1 μm and equal to or less than 0.2 μm.

The p-side contact electrode 30 may have an Rh/Ti/Rh/TiN stack structure in which a first Rh layer, a Ti layer, a second Rh layer, and a TiN layer are sequentially stacked. The first Rh layer of the p-side contact electrode is in contact with the upper surface 28a of the p-type semiconductor layer 28. The thickness of the first Rh layer of the p-side contact electrode 30 is equal to or more than 50 nm and equal to or less than 200 nm and is, for example, equal to or more than 70 nm and equal to or less than 150 nm. The thickness of the Ti layer of the p-side contact electrode is equal to or more than 1 nm and equal to or less than 50 nm and is, for example, equal to or more than 5 nm and equal to or less than 25 nm. The thickness of the second Rh layer of the p-side contact electrode 30 is equal to or more than 5 nm and equal to or less than 100 nm and is, for example, equal to or more than 10 nm and equal to or less than 50 nm. The TiN layer of the p-side contact electrode 30 is made of TiN having conductivity. The thickness of the TiN layer of the p-side contact electrode 30 is equal to or more than 5 nm and equal to or less than 100 nm and is, for example, equal to or more than 10 nm and equal to or less than 50 nm. In this case, the thickness t1 of the p-side contact electrode may be equal to or more than 0.1 μm and equal to or less than 0.4 μm.

The p-side contact electrode 30 may be made of a transparent conductive oxide (TCO) such as tin oxide (SnO₂), zinc oxide (ZnO), or indium tin oxide (ITO). The p-side contact electrode 30 may have a Ni/Au stack structure. In these cases, the thickness t1 of the p-side contact electrode may be equal to or more than 0.1 μm and equal to or less than 0.3 μm.

The p-side contact electrode 30 includes a first p-side inclined portion 30b and a first p-side base portion 30c. The first p-side inclined portion 30b and the first p-side base portion 30c are made of the same material. When the p-side contact electrode 30 has a stack structure, the first p-side inclined portion 30b and the first p-side base portion 30c can have the same stack structure.

The first p-side inclined portion 30b is a portion forming an edge of the p-side contact electrode 30, and is a portion where an upper surface 30a is inclined such that the thickness t1 decreases toward the edge of the p-side contact electrode 30. The thickness of the first p-side inclined portion 30b is equal to or less than 90% of the thickness t1 of the first p-side base portion 30c. The width of the first p-side inclined portion 30b is 10 times or more the thickness t1 of the first p-side base portion 30c. The width of the first p-side inclined portion 30b is, for example, equal to or more than 5 μm and equal to or less than 10 μm. Here, the width of the first p-side inclined portion 30b is, for example, a width in a predetermined direction indicated by the arrow B, and is a width in the direction orthogonal to the thickness direction indicated by the arrow A and orthogonal to the direction in which the edge of the p-side contact electrode 30 extends (for example, a direction penetrating through FIG. 1). As a result, the first p-side inclined portion 30b is formed such that the inclination of the upper surface 30a is gentle.

The first p-side base portion 30c is a central portion of the p-side contact electrode 30, and is a portion where the upper surface 30a is flat such that the thickness t1 is substantially constant. Here, the thickness t1 being substantially constant means that a change in thickness t1 is within +5%. The first p-side base portion 30c is a portion different from the first p-side inclined portion 30b. The thickness t1 of the first p-side base portion 30c is, for example, equal to or more than 0.1 μm and equal to or less than 1 μm.

The n-side contact electrode 32 is provided on the second upper surface 24b of the n-type semiconductor layer 24. The n-side contact electrode 32 has, for example, a Ti/Al/Ti/TiN stack structure in which a first Ti layer, an Al layer, a second Ti layer, and a TiN layer are sequentially stacked. The first Ti layer of the n-side contact electrode 32 is in contact with the second upper surface 24b of the n-type semiconductor layer 24. The thickness of the first Ti layer of the n-side contact electrode 32 is equal to or more than 1 nm and equal to or less than 10 nm and, preferably, equal to or less than 5 nm or equal to or less than 2 nm. The Al layer of the n-side contact electrode 32 is provided on the first Ti layer and is fin contact with the first Ti layer. The thickness of the Al layer of the n-side contact electrode 32 is equal to or more than 200 nm and is, for example, equal to or more than 300 nm and equal to or less than 1000 nm. The second Ti layer of the n-side contact electrode 32 is provided on the Al layer and is in contact with the Al layer. The thickness of the second Ti layer of the n-side contact electrode 32 is equal to or more than 1 nm and equal to or less than 50 nm and is, for example, equal to or more than 5 nm and equal to or less than 25 nm. The TiN layer of the n-side contact electrode 32 is provided on the second Ti layer and is in contact with the second Ti layer. The TiN layer of the n-side contact electrode 32 is made of TiN having conductivity. The thickness of the TiN layer of the n-side contact electrode 32 is equal to or more than 5 nm and equal to or less than 100 nm and is, for example, equal to or more than 10 nm and equal to or less than 50 nm. A thickness t2 of the n-side contact electrode 32 is equal to or more than 0.2 μm and equal to or less than 1 μm.

The n-side contact electrode 32 includes a first inner inclined portion 32b, a first n-side base portion 32c, and a first outer inclined portion 32d. The first inner inclined portion 32b, the first n-side base portion 32c, and the first outer inclined portion 32d are made of the same material. When the n-side contact electrode 32 has a stack structure, the first inner inclined portion 32b, the first n-side base portion 32c, and the first outer inclined portion 32d can have the same stack structure.

The first inner inclined portion 32b is a portion forming an edge of the n-side contact electrode 32, and is a portion where an upper surface 32a is inclined such that the thickness t2 decreases toward the active layer 26. The first outer inclined portion 32d is a portion forming the edge of the n-side contact electrode 32, and is a portion where the upper surface 32a is inclined such that the thickness t2 decreases as the distance from the active layer 26 increases. The thickness of each of the first inner inclined portion 32b and the first outer inclined portion 32d is equal to or less than 90% of the thickness t2 of the first n-side base portion 32c. The width of each of the first inner inclined portion 32b and the first outer inclined portion 32d is 10 times or more the thickness t2 of the first n-side base portion 32c. The width of each of the first inner inclined portion 32b and the first outer inclined portion 32d is, for example, equal to or more than 5 μm and equal to or less than 10 μm. Here, the width of each of the first inner inclined portion 32b and the first outer inclined portion 32d is, for example, a width in the predetermined direction indicated by the arrow B, and is a width in the direction orthogonal to the thickness direction indicated by the arrow A and orthogonal to the direction in which the edge of the n-side contact electrode 32 extends (for example, a direction penetrating through FIG. 1).

The first n-side base portion 32c is a central portion of the n-side contact electrode 32, and is a portion where the upper surface 32a is flat such that the thickness t2 is substantially constant. Here, the thickness t2 being substantially constant means that a change in thickness t2 is within +5%. The first n-side base portion 32c is a portion different from the first inner inclined portion 32b and the first outer inclined portion 32d. The thickness t2 of the first n-side base portion 32c is, for example, equal to or more than 0.1 μm and equal to or less than 1 μm or less, preferably, equal to or more than 0.2 μm, and more preferably, equal to or more than 0.5 μm.

The p-side current diffusion layer 34 is provided to cover the entire p-side contact electrode 30. The p-side current diffusion layer 34 has a structure in which a first TiN layer, a metal layer, and a second TiN layer are sequentially stacked. The p-side current diffusion layer 34 may further include an additional metal layer provided under the first TiN layer. The p-side current diffusion layer 34 has, for example, a Ti/TiN/Ti/Rh/TiN stack structure in which a first TiN layer, a Ti layer, an Rh layer, a second TiN layer, a Ti layer, and an Au layer are sequentially stacked. The p-side current diffusion layer 34 may further include an additional metal layer provided on the second TiN layer. The p-side current diffusion layer 34 may have a Ti/TiN/Ti/Rh/TiN/Ti/Au stack structure.

The first TiN layer and the second TiN layer of the p-side current diffusion layer 34 are made of TiN having conductivity. The thickness of each of the first TiN layer and the second TiN layer of the p-side current diffusion layer 34 is equal to or more than 10 nm and equal to or less than 200 nm and is, for example, equal to or more than 50 nm and equal to or less than 150 nm. The thickness of each of the Ti layer and the Rh layer provided between the first TiN layer and the second TiN layer of the p-side current diffusion layer 34 is equal to or more than 10 nm and equal to or less than 200 nm and is, for example, equal to or more than 20 nm and equal to or less than 150 nm. The p-side current diffusion layer 34 may include a plurality of Ti layers and a plurality of Rh layers that are alternately stacked between the first TiN layer and the second TiN layer. The thickness of the Ti layer provided under the first TiN layer of the p-side current diffusion layer 34 is equal to or more than 1 nm and equal to or less than 50 nm and is, for example, equal to or more than 5 nm and equal to or less than nm. The thickness of the Ti layer provided on the second TiN layer of the p-side current diffusion layer 34 is equal to or more than 1 nm and equal to or less than 50 nm and is, for example, equal to or more than 5 nm and equal to or less than 25 nm. The Au layer of the p-side current diffusion layer 34 is equal to or more than 100 nm and equal to or less than 500 nm and is, for example, equal to or more than 150 nm and equal to or less than 300 nm. A thickness t3 of the p-side current diffusion layer 34 is, for example, equal to or more than 0.2 μm and equal to or less than 1 μm.

The p-side current diffusion layer 34 includes a second p-side inclined portion 34b and a second p-side base portion 34c. The second p-side inclined portion 34b and the second p-side base portion 34c are made of the same material. When the p-side current diffusion layer 34 has a stack structure, the second p-side inclined portion 34b and the second p-side base portion 34c can have the same stack structure.

The second p-side inclined portion 34b is a portion forming an edge of the p-side current diffusion layer 34, and is a portion where an upper surface 34a is inclined such that a height h1 of the upper surface 34a decreases toward the edge of the p-side current diffusion layer 34. Here, the height h1 of the upper surface 34a of the p-side current diffusion layer 34 is, for example, a distance in the thickness direction from an upper surface 28a of the p-type semiconductor layer 28, and corresponds to the sum of the thickness t1 of the p-side contact electrode 30 and the thickness t3 of the p-side current diffusion layer 34. The height of the upper surface 34a of the second p-side inclined portion 34b is equal to or less than 90% of the height h1 of the upper surface 34a of the second p-side base portion 34c. The width of the second p-side inclined portion 34b is 10 times or more the height h1 of the upper surface 34a of the second p-side base portion 34c. The width of the second p-side inclined portion 34b is, for example, equal to or more than 5 μm and equal to or less than 20 μm. Here, the width of the second p-side inclined portion 34b is, for example, a width in the predetermined direction indicated by the arrow B, and is a width in the direction orthogonal to the thickness direction indicated by the arrow A and orthogonal to a direction in which the edge of the p-side current diffusion layer 34 extends (a direction penetrating through FIG. 1). As a result, the second p-side inclined portion 34b is formed such that the inclination of the upper surface 34a is gentle. The second p-side inclined portion 34b includes an overlapping portion overlapping the first p-side inclined portion 30b and a non-overlapping portion not overlapping the first p-side inclined portion 30b. The non-overlapping portion of the second p-side inclined portion 34b is in contact with the upper surface 28a of the p-type semiconductor layer 28.

The second p-side base portion 34c is a central portion of the p-side current diffusion layer 34, and is a portion where the upper surface 34a is flat such that the height h1 of the upper surface 34a of the p-side current diffusion layer 34 is substantially constant. The height h1 of the upper surface 34a of the p-side current diffusion layer 34 being substantially constant means that a change in height h1 is within +5%. The second p-side base portion 34c is a portion different from the second p-side inclined portion 34b. A thickness t3 of the second p-side base portion 34c is, for example, equal to or more than 0.1 μm and equal to or less than 1 μm. The height h1 of the upper surface 34a of the second p-side base portion 34c is, for example, equal to or more than 0.2 μm and equal to or less than 2 μm. The second p-side base portion 34c overlaps the first p-side base portion 30c. The second p-side base portion 34c does not overlap the first p-side inclined portion 30b.

The n-side current diffusion layer 36 is provided to cover the entire n-side contact electrode 32. Similarly to the p-side current diffusion layer 34, the n-side current diffusion layer 36 has a structure in which a first TiN layer, a metal layer, and a second TiN layer are sequentially stacked. The n-side current diffusion layer 36 may further include an additional metal layer provided under the first TiN layer. The n-side current diffusion layer 36 has, for example, a TiN/Ti/Rh/TiN/Ti/Au stack structure in which a first TiN layer, a Ti layer, an Rh layer, a second TiN layer, a Ti layer, and an Au layer are sequentially stacked. The n-side current diffusion layer 36 may further include an additional metal layer provided on the second TiN layer. The n-side current diffusion layer 36 may have a Ti/TiN/Ti/Rh/TiN/Ti/Au stack structure.

The first TiN layer and the second TiN layer of the n-side current diffusion layer 36 are made of TiN having conductivity. The thickness of each of the first TiN layer and the second TiN layer of the n-side current diffusion layer 36 is equal to or more than 10 nm and equal to or less than 200 nm and is, for example, equal to or more than 50 nm and equal to or less than 150 nm. The thickness of each of the Ti layer and the Rh layer provided between the first TiN layer and the second TiN layer of the n-side current diffusion layer 36 is equal to or more than 10 nm and equal to or less than 200 nm and is, for example, equal to or more than 20 nm and equal to or less than 150 nm. The n-side current diffusion layer 36 may include a plurality of Ti layers and a plurality of Rh layers that are alternately stacked between the first TiN layer and the second TiN layer. The thickness of the Ti layer provided under the first TiN layer of the n-side current diffusion layer 36 is equal to or more than 1 nm and equal to or less than 50 nm and is, for example, equal to or more than 5 nm and equal to or less than nm. The thickness of the Ti layer provided on the second TiN layer of the n-side current diffusion layer 36 is equal to or more than 1 nm and equal to or less than 50 nm and is, for example, equal to or more than 5 nm and equal to or less than 25 nm. The Au layer of the n-side current diffusion layer 36 is equal to or more than 100 nm and equal to or less than 500 nm and is, for example, equal to or more than 150 nm and equal to or less than 300 nm. A thickness t4 of the n-side current diffusion layer 36 is, for example, equal to or more than 0.2 μm and equal to or less than 1 μm.

The n-side current diffusion layer 36 includes a second inner inclined portion 36b, a second n-side base portion 36c, and a second outer inclined portion 36d. The second inner inclined portion 36b, the second n-side base portion 36c, and the second outer inclined portion 36d are made of the same material. When the n-side current diffusion layer 36 has a stack structure, the second inner inclined portion 36b, the second n-side base portion 36c, and the second outer inclined portion 36d can have the same stack structure.

The second inner inclined portion 36b is a portion forming an edge of the n-side current diffusion layer 36, and is a portion where an upper surface 36a is inclined such that a height h2 of the upper surface 36a decreases toward the active layer 26. The second outer inclined portion 36d is a portion forming the edge of the n-side current diffusion layer 36, and is a portion where the upper surface 36a is inclined such that the height h2 of the upper surface 36a decreases as the distance from the active layer 26 increases. The width of each of the second inner inclined portion 36b and the second outer inclined portion 36d is 10 times or more the height h2 of the second n-side base portion 36c. Here, the height h2 of the upper surface 36a of the n-side current diffusion layer 36 is a distance in the thickness direction from a second upper surface 24b of the n-type semiconductor layer 24, and corresponds to the sum of the thickness t2 of the n-side contact electrode 32 and the thickness t4 of the n-side current diffusion layer 36. The height of the upper surface 36a of each of the second inner inclined portion 36b and the second outer inclined portion 36d is equal to or less than 90% of the height h2 of the upper surface 36a of the second n-side base portion 36c. The width of each of the second inner inclined portion 36b and the second outer inclined portion 36d is, for example, equal to or more than 5 μm and equal to or less than 20 μm. Here, the width of each of the second inner inclined portion 36b and the second outer inclined portion 36d is, for example, a width in the direction indicated by the arrow B, and is a width in the direction orthogonal to the thickness direction indicated by the arrow A and orthogonal to a direction in which the edge of the n-side current diffusion layer 36 extends (for example, a direction penetrating through FIG. 1). As a result, the second inner inclined portion 36b and the second outer inclined portion 36d are formed such that the inclination of the upper surface 36a is gentle. Each of the second inner inclined portion 36b and the second outer inclined portion 36d includes an overlapping portion overlapping the first inner inclined portion 32b or the first outer inclined portion 32d and a non-overlapping portion not overlapping the first inner inclined portion 32b or the first outer inclined portion 32d. The non-overlapping portion of each of the second inner inclined portion 36b and the second outer inclined portion 36d is in contact with the second upper surface 24b of the n-type semiconductor layer 24.

The second n-side base portion 36c is a central portion of the n-side current diffusion layer 36, and is a portion where the upper surface 36a is flat such that the height h2 of the upper surface 36a of the n-side current diffusion layer 36 is substantially constant. The height h2 of the upper surface 36a of the n-side current diffusion layer 36 being substantially constant means that a change in height h2 is within +5%. The second n-side base portion 36c is a portion different from the second inner inclined portion 36b and the second outer inclined portion 36d. The height h2 of the upper surface 36a of the second n-side base portion 36c is, for example, equal to or more than 0.2 μm and equal to or less than 2 μm. The thickness t4 of the second n-side base portion 36c is, for example, equal to or more than 0.1 μm and equal to or less than 1 μm. The second n-side base portion 36c overlaps the first n-side base portion 32c. The second n-side base portion 36c does not overlap the first inner inclined portion 32b and the first outer inclined portion 32d.

The first protective layer 38 is provided to cover the entirety of the element from above. The first protective layer 38 covers the n-type semiconductor layer 24, the active layer 26, the p-type semiconductor layer 28, the p-side contact electrode 30, the n-side contact electrode 32, the p-side current diffusion layer 34, and the n-side current diffusion layer 36. The first protective layer 38 has a first p-side pad opening 38p provided on the p-side current diffusion layer 34 and a first n-side pad opening 38n provided on the n-side current diffusion layer 36. The first protective layer 38 covers the p-side current diffusion layer 34 in a portion different from that of the first p-side pad opening 38p and covers the n-side current diffusion layer 36 in a portion different from that of the first n-side pad opening 38n. The first protective layer 38 is in contact with the base layer 22 at the outer circumference of the n-type semiconductor layer 24. The first protective layer 38 is in contact with the upper surface 22a of the base layer 22, is in contact with the second upper surface 24b and the side surface 24c of the n-type semiconductor layer 24, is in contact with the side surface of the active layer 26, is in contact with the upper surface 28a and the side surface of the p-type semiconductor layer 28, is in contact with the p-side current diffusion layer 34, and is in contact with the n-side current diffusion layer 36.

The first p-side pad opening 38p is provided at a position overlapping the second p-side base portion 34c of the p-side current diffusion layer 34. The first p-side pad opening 38p is provided, for example, at a position not overlapping the second p-side inclined portion 34b of the p-side current diffusion layer 34. The first n-side pad opening 38n is provided at a position overlapping the second n-side base portion 36c of the n-side current diffusion layer 36. The first n-side pad opening 38n is provided, for example, at a position not overlapping the second inner inclined portion 36b and the second outer inclined portion 36d of the n-side current diffusion layer 36.

The first protective layer 38 is made of an oxide dielectric material such as silicon oxide (SiO₂), aluminum oxide (Al₂O₃), and hafnium oxide (HfO₂). The first protective layer 38 is preferably made of SiO₂. The thickness of the first protective layer 38 is equal to or more than 300 nm and equal to or less than 1500 nm and is, for example, equal to or more than 600 nm and equal to or less than 1000 nm.

The second protective layer 40 is provided to cover the entirety of the element from above and is provided to cover the entirety of the surface of the first protective layer 38. The second protective layer 40 has a second p-side pad opening 40p provided on the p-side current diffusion layer 34 and a second n-side pad opening 40n provided on the n-side current diffusion layer 36. The second protective layer 40 covers the first protective layer 38 in a portion different from portions of the second p-side pad opening 40p and the second n-side pad opening 40n. The second protective layer 40 is also provided inside each of the first p-side pad opening 38p and the first n-side pad opening 38n. The second protective layer 40 covers an inner circumferential surface 38a of the first protective layer 38 that defines the first p-side pad opening 38p and covers an inner circumferential surface 38b of the first protective layer 38 that defines the first n-side pad opening 38n. The second protective layer 40 is in contact with the base layer 22 at the outer circumference of the first protective layer 38. The second protective layer 40 is in contact with the upper surface 22a of the base layer 22, is in contact with the inner circumferential surfaces 38a and 38b of the first protective layer 38, is in contact with the p-side current diffusion layer 34, and is in contact with the n-side current diffusion layer 36.

The second p-side pad opening 40p is provided at a position overlapping the second p-side base portion 34c of the p-side current diffusion layer 34. The second p-side pad opening 40p is provided, for example, at a position not overlapping the second p-side inclined portion 34b of the p-side current diffusion layer 34. The second n-side pad opening 40n is provided at a position overlapping the second n-side base portion 36c of the n-side current diffusion layer 36. The first n-side pad opening 38n is provided, for example, at a position not overlapping the second inner inclined portion 36b and the second outer inclined portion 36d of the n-side current diffusion layer 36.

The second protective layer 40 is made of silicon nitride (SiNₓ), which is a dielectric material having high moisture resistance. The thickness of the second protective layer 40 is equal to or more than 50 nm and equal to or less than 500 nm and is, for example, equal to or more than 100 nm and equal to or less than 400 nm.

The p-side pad electrode 42 and the n-side pad electrode 44 are portions bonded when the semiconductor light-emitting element 10 is mounted on a submount substrate or the like. The p-side pad electrode 42 and the n-side pad electrode 44 include, for example, a Ni/Au, Ti/Au, or Ti/Pt/Au stack structure. The thickness of each of the p-side pad electrode 42 and the n-side pad electrode 44 is equal to or more than 100 nm and is, for example, equal to or more than 200 nm and equal to or less than 1000 nm.

The p-side pad electrode 42 is provided on the p-side current diffusion layer 34 and is in contact with the p-side current diffusion layer 34 in the second p-side pad opening 40p. The p-side pad electrode 42 is electrically connected to the p-side contact electrode 30 via the p-side current diffusion layer 34. The p-side pad electrode 42 is provided to block the second p-side pad opening 40p and overlaps the second protective layer 40 outside the second p-side pad opening 40p. The p-side pad electrode 42 may overlap the first protective layer 38 outside the first p-side pad opening 38p. The p-side pad electrode 42 is in contact with the second p-side base portion 34c of the p-side current diffusion layer 34. The p-side pad electrode 42 is not in contact with the second p-side inclined portion 34b of the p-side current diffusion layer 34. The p-side pad electrode 42 may overlap the second p-side inclined portion 34b of the p-side current diffusion layer 34.

The n-side pad electrode 44 is provided on the n-side current diffusion layer 36 and is in contact with the n-side current diffusion layer 36 in the second n-side pad opening 40n. The n-side pad electrode 44 is electrically connected to the n-side contact electrode 32 via the n-side current diffusion layer 36. The n-side pad electrode 44 is provided to block the second n-side pad opening 40n and overlaps the second protective layer 40 outside the second n-side pad opening 40n. The n-side pad electrode 44 may overlap the first protective layer 38 outside the first n-side pad opening 38n. The n-side pad electrode 44 is in contact with the second n-side base portion 36c of the n-side current diffusion layer 36. The n-side pad electrode 44 is not in contact with the second inner inclined portion 36b and the second outer inclined portion 36d of the n-side current diffusion layer 36. The n-side pad electrode 44 may overlap the second inner inclined portion 36b and the second outer inclined portion 36d of the n-side current diffusion layer 36.

FIG. 2 is a cross sectional view schematically showing an inclined structure of a contact electrode 52 and a current diffusion layer 54 according to the first embodiment. FIG. 2 shows a structure in which the contact electrode 52, the current diffusion layer 54, a first protective layer 56, a second protective layer 58, and a pad electrode 60 are stacked on a semiconductor layer 50.

The semiconductor layer 50 corresponds to the n-type semiconductor layer 24 or the p-type semiconductor layer 28 described above. The first protective layer 56 and the second protective layer 58 correspond to the first protective layer 38 and the second protective layer 40 described above, respectively. When the semiconductor layer 50 is the p-type semiconductor layer 28, the contact electrode 52 is the p-side contact electrode 30, the current diffusion layer 54 is the p-side current diffusion layer 34, and the pad electrode 60 is the p-side pad electrode 42. When the semiconductor layer 50 is the n-type semiconductor layer 24, the contact electrode 52 is the n-side contact electrode 32, the current diffusion layer 54 is the n-side current diffusion layer 36, and the pad electrode 60 is the n-side pad electrode 44.

The contact electrode 52 includes a first inclined portion 52b and a first base portion 52c. The first inclined portion 52b corresponds to the first p-side inclined portion 30b, the first inner inclined portion 32b, or the first outer inclined portion 32d described above. The first inclined portion 52b is a portion where a thickness t5 decreases toward an edge of the contact electrode 52. The first inclined portion 52b is, for example, a portion where the thickness of the first inclined portion 52b is equal to or less than 90% of the thickness t5 of the first base portion 52c. A width w1 of the first inclined portion 52b in the predetermined direction indicated by the arrow B is 10 times or more the thickness t5 of the first base portion 52c. The width w1 of the first inclined portion 52b in the predetermined direction indicated by the arrow B is, for example, equal to or more than 5 μm and equal to or less than 10 μm. The first base portion 52c corresponds to the first p-side base portion 30c or the first n-side base portion 32c described above. The first base portion 52c is a portion where an upper surface 52a is flat such that the thickness t5 of the contact electrode 52 is substantially constant. The thickness t5 of the first base portion 52c is, for example, equal to or more than 0.1 μm and equal to or less than 1 μm.

The current diffusion layer 54 includes a second inclined portion 54b and a second base portion 54c. The second inclined portion 54b corresponds to the second p-side inclined portion 34b, the second inner inclined portion 36b, or the second outer inclined portion 36d described above. The second inclined portion 54b is a portion where a height h3 of an upper surface 54a decreases toward an edge of the current diffusion layer 54. The second inclined portion 54b is, for example, a portion where the height of the upper surface 54a of the second inclined portion 54b is equal to or less than 90% of the height h3 of the upper surface 54a of the second base portion 54c. A width w2 of the second inclined portion 54b in the predetermined direction indicated by the arrow B is 10 times or more the height h3 of the upper surface 54a of the second base portion 54c. The height h3 of the upper surface 54a of the second base portion 54c is a height from an upper surface 50a of the semiconductor layer 50, and corresponds to the sum of the thickness t5 of the first base portion 52c and a thickness t6 of the second base portion 54c. The width w2 of the second inclined portion 54b in the predetermined direction indicated by the arrow B is, for example, equal to or more than 5 μm and equal to or less than 20 μm. The second base portion 54c corresponds to the second p-side base portion 34c or the second n-side base portion 36c described above. The second base portion 54c is a portion where the upper surface 54a is flat such that the height h3 of the upper surface 54a of the current diffusion layer 54 is substantially constant. The height h3 of the upper surface 54a of the second base portion 54c is, for example, equal to or more than 0.2 μm and equal to or less than 2 μm. The thickness t6 of the second base portion 54c is, for example, equal to or more than 0.1 μm and equal to or less than 1 μm.

The second inclined portion 54b includes a non-overlapping portion 54e and an overlapping portion 54f. The non-overlapping portion 54e is a portion of the second inclined portion 54b not overlapping the first inclined portion 52b. In the example of FIG. 2, the non-overlapping portion 54e is a portion not overlapping the contact electrode 52, and is provided outside the edge of the contact electrode 52. The thickness t6 of the non-overlapping portion 54e decreases toward the edge of the current diffusion layer 54. The overlapping portion 54f is a portion of the second inclined portion 54b overlapping the first inclined portion 52b. In the example of FIG. 2, the overlapping portion 54f is a portion overlapping the contact electrode 52, and is provided inside the edge of the contact electrode 52. The overlapping portion 54f includes a first overlapping portion 54g in which the thickness t6 of the current diffusion layer 54 changes and a second overlapping portion 54h in which the thickness t6 of the current diffusion layer 54 is substantially constant. The thickness t6 of the first overlapping portion 54g decreases toward the edge of the current diffusion layer 54, that is, from the second overlapping portion 54h toward the non-overlapping portion 54e.

A width w3 of the non-overlapping portion 54e in the predetermined direction indicated by the arrow B is equal to or more than half of the width w1 of the first inclined portion 52b, and preferably equal to or more than 60%. The width w3 of the non-overlapping portion 54e is, for example, equal to or more than 2 μm and equal to or less than 10 μm. A width w4 of the first overlapping portion 54g in the predetermined direction indicated by the arrow B is less than half of the width w1 of the first inclined portion 52b, and preferably equal to or less than 40%. The width w4 of the first overlapping portion 54g is, for example, equal to or more than 1 μm and equal to or less than 5 μm. A width w5 of the second overlapping portion 54h in the predetermined direction indicated by the arrow B is equal to or more than half of the width w1 of the first inclined portion 52b, and is preferably equal to or more than 60%. The width w5 of the second overlapping portion 54h is, for example, equal to or more than 2 μm and equal to or less than 10 μm.

The first protective layer 56 has a first pad opening 56c provided at a position overlapping the second base portion 54c. The first pad opening 56c corresponds to the first n-side pad opening 38n or the first p-side pad opening 38p described above. The second protective layer 58 has a second pad opening 58c provided at a position overlapping the second base portion 54c. The second pad opening 58c corresponds to the second n-side pad opening 40n or the second p-side pad opening 40p described above. The second protective layer 58 covers an inner circumferential surface 56a of the first protective layer 56 that defines the first pad opening 56c. The pad electrode 60 is in contact with the upper surface 54a of the current diffusion layer 54 in the first pad opening 56c and the second pad opening 58c.

In the configuration of FIG. 2, the inclination of the upper surface 54a of the current diffusion layer 54 tends to increase at the position of the first overlapping portion 54g. This is because the inclination of the upper surface 54a of the first overlapping portion 54g corresponds to the sum of the contribution of the inclination of the first inclined portion 52b whose thickness t5 changes and the contribution of the inclination of the first overlapping portion 54g whose thickness t6 changes. In the configuration of FIG. 2, the width w4 of the first overlapping portion 54g where the inclination of the upper surface 54a tends to increase can be relatively decreased by relatively decreasing the width w4 of the first overlapping portion 54g. As a result, the inclinations of the first protective layer 56, the second protective layer 58, and the pad electrode 60 stacked on the upper surface 54a of the current diffusion layer 54 can be decreased, and the thicknesses of the first protective layer 56, the second protective layer 58, and the pad electrode 60 can be made uniform. As a result, it is possible to prevent the first protective layer 56 and the second protective layer 58 from being locally decreased in thickness to deteriorate a covering property. In addition, it is possible to prevent a decrease in conductivity due to a local decrease in thickness of the pad electrode 60. As a result, the reliability of the semiconductor light-emitting element 10 can be improved.

In addition, the inclination of the upper surface 52a of the first inclined portion 52b can be decreased by setting the width w1 of the first inclined portion 52b to 10 times or more the thickness t5 of the first base portion 52c. Similarly, the inclination of the upper surface 54a of the second inclined portion 54b can be decreased by setting the width w2 of the second inclined portion 54b to 10 times or more the height h3 of the upper surface 54a of the second base portion 54c. As a result, the inclinations of the first protective layer 56, the second protective layer 58, and the pad electrode 60 stacked on the upper surface 54a of the current diffusion layer 54 can be decreased, and the thicknesses of the first protective layer 56, the second protective layer 58, and the pad electrode 60 can be made uniform. As a result, it is possible to prevent the first protective layer 56 and the second protective layer 58 from being locally decreased in thickness to deteriorate a covering property. In addition, it is possible to prevent a decrease in conductivity due to a local decrease in thickness of the pad electrode 60. As a result, the reliability of the semiconductor light-emitting element 10 can be improved.

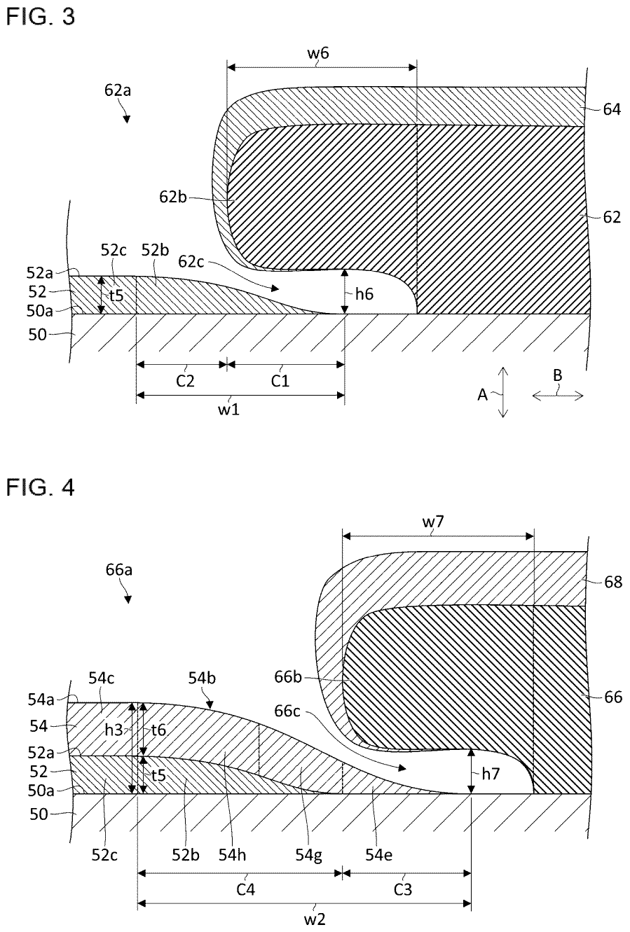

FIG. 3 is a cross sectional view schematically showing a step of forming the contact electrode 52 according to the first embodiment. First, a first resist 62 is formed on the upper surface 50a of the semiconductor layer 50. The first resist 62 can be formed using a lithographic technology. The first resist 62 has a first opening 62a positioned in a region in which the contact electrode 52 is to be formed, and is formed in a region excluding the first opening 62a. The first opening 62a of the first resist 62 has a so-called undercut shape. The first resist 62 has an eaves portion 62b protruding toward the first opening 62a. An undercut-shaped gap 62c is provided between the upper surface 50a of the semiconductor layer 50 and the eaves portion 62b. A height h6 of the undercut-shaped gap 62c is equal to or more than 0.1 μm and equal to or less than 1 μm. A width w6 of the undercut-shaped gap 62c in the predetermined direction indicated by the arrow B is equal to or more than 5 μm and equal to or less than 10 μm.

Next, an electrode layer 64 is deposited on the first resist 62 to form the contact electrode 52 in the first opening 62a. The electrode layer 64 can be deposited using, for example, a sputtering method. By using the sputtering method, sputtered particles having an angular distribution (for example, +10 degrees or more) can be incident on the upper surface 50a of the semiconductor layer 50. As a result, the sputtered particles can effectively reach the back side of the undercut-shaped gap 62c, and the width w1 of the first inclined portion 52b of the contact electrode 52 can be increased. The first inclined portion 52b of the contact electrode 52 is formed over a region C1 overlapping the first resist 62 (eaves portion 62b) and a region C2 not overlapping the first resist 62. After the contact electrode 52 is formed, the first resist 62 is removed.

FIG. 4 is a cross sectional view schematically showing a step of forming the current diffusion layer 54 according to the first embodiment. First, a second resist 66 is formed on the upper surface 50a of the semiconductor layer 50. The second resist 66 can be formed using a lithographic technology. The second resist 66 has a second opening 66a positioned in a region in which the current diffusion layer 54 is to be formed, and is formed in a region excluding the second opening 66a. The second opening 66a of the second resist 66 has a so-called undercut shape. The second resist 66 has an eaves portion 66b protruding toward the second opening 66a. An undercut-shaped gap 66c is provided between the upper surface 50a of the semiconductor layer 50 and the eaves portion 66b. A height h7 of the undercut-shaped gap 66c is equal to or more than 0.1 μm and equal to or less than 1 μm. A width w7 of the undercut-shaped gap 66c in the predetermined direction indicated by the arrow B is equal to or more than 5 μm and equal to or less than 10 μm. The second resist 66 is formed, for example, at a position not overlapping the contact electrode 52.

Next, a stack structure 68 is deposited on the second resist 66 to form the current diffusion layer 54 in the second opening 66a. The stack structure 68 has, for example, a structure in which Ti/TiN/Ti/Rh/TiN are sequentially stacked. The stack structure 68 can be deposited using, for example, a sputtering method. By using the sputtering method, sputtered particles having an angular distribution (for example, +10 degrees or more) can be incident on the upper surface 50a of the semiconductor layer 50. As a result, the sputtered particles can effectively reach the back side of the undercut-shaped gap 66c, and the width w2 of the second inclined portion 54b of the current diffusion layer 54 can be increased. The second inclined portion 54b of the current diffusion layer 54 is formed over a region C3 overlapping the second resist 66 (eaves portion 66b) and a region C4 not overlapping the second resist 66. The non-overlapping portion 54e of the second inclined portion 54b is formed, for example, in the region C3 overlapping the second resist 66 (eaves portion 66b). The first overlapping portion 54g and the second overlapping portion 54h of the second inclined portion 54b are formed, for example, in the region C4 not overlapping the second resist 66. After the current diffusion layer 54 is formed, the second resist 66 is removed.

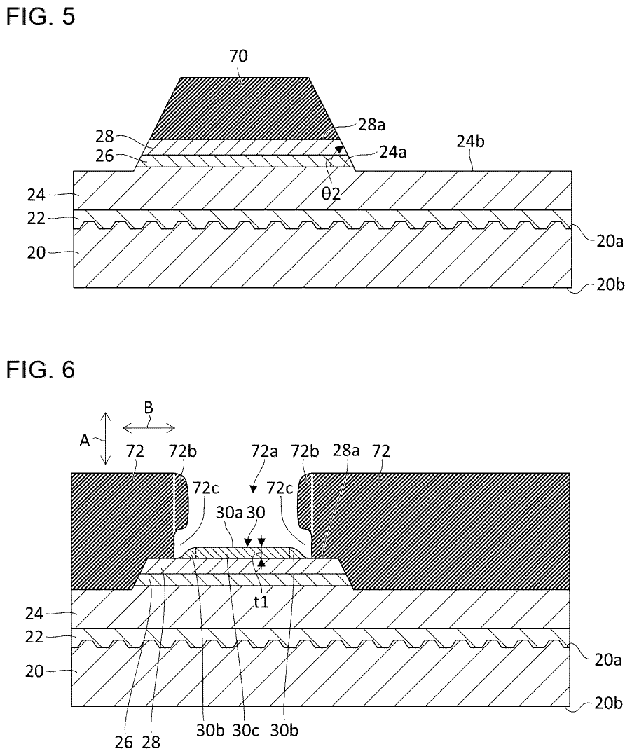

A description will now be given of a method of manufacturing the semiconductor light-emitting element 10 according to the first embodiment. FIGS. 5 to 13 schematically show steps of manufacturing the semiconductor light-emitting element 10 according to the first embodiment. First, referring to FIG. 5, the base layer 22, the n-type semiconductor layer 24, the active layer 26, and the p-type semiconductor layer 28 are formed on the first principal surface 20a of the substrate 20 sequentially.

The substrate 20 is, for example, a patterned sapphire substrate. The base layer 22 includes, for example, an HT-AlN layer and an undoped AlGaN layer. The n-type semiconductor layer 24, the active layer 26, and the p-type semiconductor layer 28 are semiconductor layers made of an AlGaN-based semiconductor material, an AlN-based semiconductor material, or a GaN-based semiconductor material and can be formed by a well-known epitaxial growth method such as the metal organic vapor phase epitaxy (MOVPE) method and the molecular beam epitaxy (MBE) method.

Subsequently, as shown in FIG. 5, a mask 70 is formed on the upper surface 28a of the p-type semiconductor layer 28 by using, for example, a publicly known lithographic technology. The p-type semiconductor layer 28 and the active layer 26 in a region not overlapping the mask 70 are removed by dry-etching or the like while the mask 70 is formed, to expose the second upper surface 24b of the n-type semiconductor layer 24. This etching step forms the second upper surface 24b of the n-type semiconductor layer 24. The mask 70 is then removed.

Next, as shown in FIG. 6, a first p-side resist 72 having a first p-side opening 72a positioned on the upper surface 28a of the p-type semiconductor layer 28 is formed. The first p-side resist 72 is formed in a region different from the first p-side opening 72a. The first p-side resist 72 can be formed in the same manner as the first resist 62 in FIG. 3. The first p-side resist 72 has an eaves portion 72b protruding toward the first p-side opening 72a, and an undercut-shaped gap 72c is provided between the upper surface 28a of the p-type semiconductor layer 28 and the eaves portion 72b. Subsequently, by depositing an electrode layer from above the first p-side resist 72, the p-side contact electrode 30 is formed on the upper surface 28a of the p-type semiconductor layer 28 in the first p-side opening 72a. The electrode layer for forming the p-side contact electrode 30 can be formed using a sputtering method. By using the first p-side resist 72 having the undercut-shaped first p-side opening 72a, the p-side contact electrode 30 including the first p-side inclined portion 30b can be formed. After the p-side contact electrode 30 is formed, the first p-side resist 72 is removed.

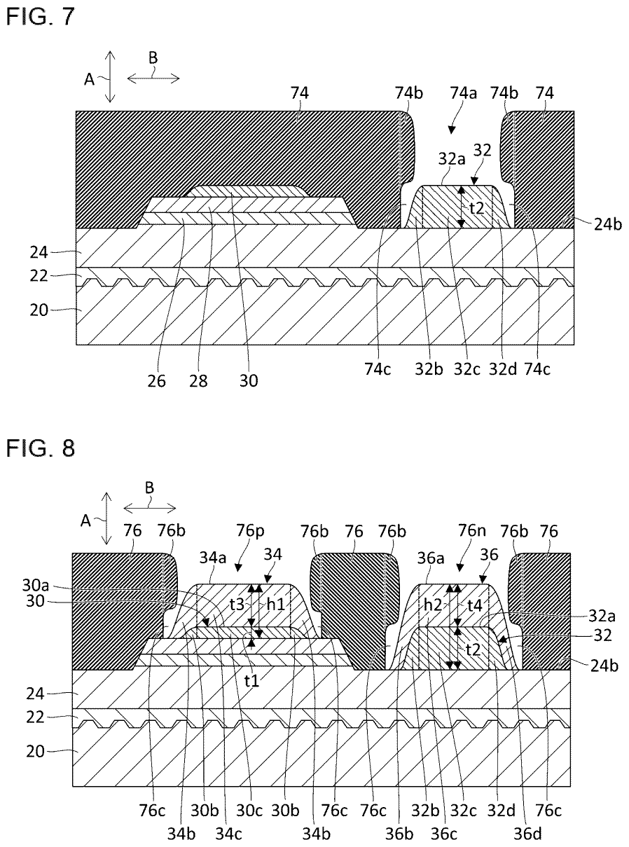

Next, as shown in FIG. 7, a first n-side resist 74 having a first n-side opening 74a positioned on the second upper surface 24b of the n-type semiconductor layer 24 is formed. The first n-side resist 74 is formed in a region different from the first n-side opening 74a. The first n-side resist 74 can be formed in the same manner as the first resist 62 in FIG. 3. The first n-side resist 74 has an eaves portion 74b protruding toward the first n-side opening 74a, and an undercut-shaped gap 74c is provided between the second upper surface 24b of the n-type semiconductor layer 24 and the eaves portion 74b. Subsequently, by depositing an electrode layer from above the first n-side resist 74, the n-side contact electrode 32 is formed on the second upper surface 24b of the n-type semiconductor layer 24 in the first n-side opening 74a. The electrode layer for forming the n-side contact electrode 32 can be formed using a sputtering method. By using the first n-side resist 74 having the undercut-shaped first n-side opening 74a, the n-side contact electrode 32 including the first inner inclined portion 32b and the first outer inclined portion 32d can be formed. After the n-side contact electrode 32 is formed, the first n-side resist 74 is removed.

The order of the steps in FIGS. 6 and 7 may be changed. That is, the step of forming the p-side contact electrode 30 shown in FIG. 6 may be executed after the step of forming the n-side contact electrode 32 shown in FIG. 7.

Next, as shown in FIG. 8, a second resist 76 having a second p-side opening 76p positioned on the upper surface 28a of the p-type semiconductor layer 28 and having a second n-side opening 76n positioned on the second upper surface 24b of the n-type semiconductor layer 24 is formed. The second resist 76 is formed in a region different from the second p-side opening 76p and the second n-side opening 76n. The second resist 76 is formed in the same manner as the second resist 66 in FIG. 4. The second resist 76 has an eaves portion 76b protruding toward the second p-side opening 76p or the second n-side opening 76n. An undercut-shaped gap 76c is provided between the upper surface 28a of the p-type semiconductor layer 28 and the eaves portion 74b and between the second upper surface 24b of the n-type semiconductor layer 24 and the eaves portion 74b. The second resist 76 is formed such that each of the p-side contact electrode 30 and the n-side contact electrode 32 does not overlap the eaves portion 76b.

Subsequently, by depositing a stack structure from above the second resist 76, the p-side current diffusion layer 34 is formed on the p-side contact electrode 30 in the second p-side opening 76p, and the n-side current diffusion layer 36 is formed on the n-side contact electrode 32 in the second n-side opening 76n. The stack structure for forming the p-side current diffusion layer 34 and the n-side current diffusion layer 36 can be formed using a sputtering method. By using the second resist 76 having the undercut-shaped second p-side opening 76p, the p-side current diffusion layer 34 including the second p-side inclined portion 34b can be formed. In addition, by using the second resist 76 having the undercut-shaped second n-side opening 76n, the n-side current diffusion layer 36 including the second inner inclined portion 36b and the second outer inclined portion 36d can be formed. After the p-side current diffusion layer 34 and the n-side current diffusion layer 36 are formed, the second resist 76 is removed.

The p-side current diffusion layer 34 and the n-side current diffusion layer 36 may be formed separately. For example, the p-side current diffusion layer 34 may be formed using a second p-side resist having only the second p-side opening 76p, and the n-side current diffusion layer 36 may be formed using a second n-side resist having only the second n-side opening 76n. In this case, the n-side current diffusion layer 36 may be formed after the p-side current diffusion layer 34 is formed, or the p-side current diffusion layer 34 may be formed after the n-side current diffusion layer 36 is formed.

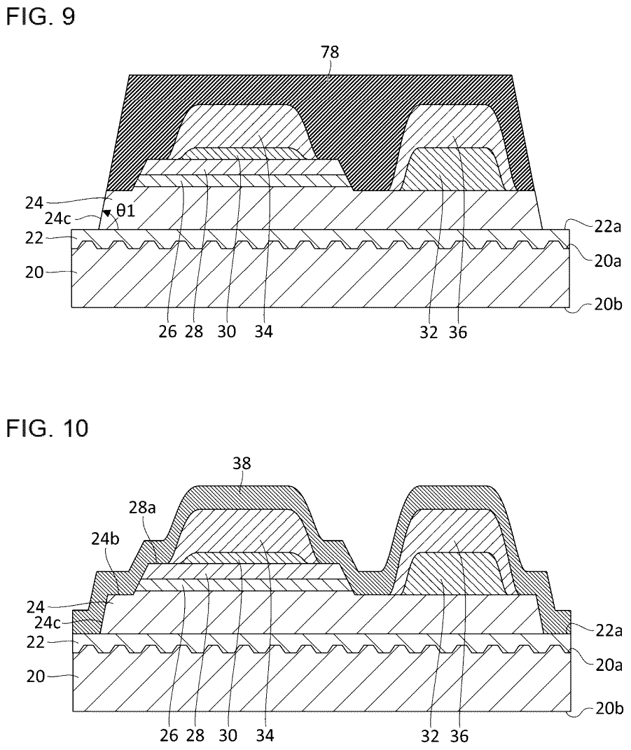

Subsequently, as shown in FIG. 9, a mask 78 is formed on the n-type semiconductor layer 24, the active layer 26, the p-type semiconductor layer 28, the p-side current diffusion layer 34, and the n-side current diffusion layer 36 by using, for example, a publicly known lithographic technology. An outer circumferential portion of the n-type semiconductor layer 24 in a region not overlapping the mask 78 is removed by dry-etching or the like while the mask 78 is formed to expose the upper surface 22a of the base layer 22. This etching step forms the side surface 24c of the n-type semiconductor layer 24. The mask 78 is then removed.

Subsequently, as shown in FIG. 10, the first protective layer 38 is formed to cover the entirety of the element from above. The first protective layer 38 can be made of, for example, SiO₂, and can be formed by plasma enhanced chemical vapor deposition (PECVD). The first protective layer 38 is formed to be in contact with and to cover the upper surface 22a of base layer 22, the second upper surface 24b and the side surface 24c of the n-type semiconductor layer 24, the side surface of the active layer 26, the upper surface 28a and the side surface of the p-type semiconductor layer 28, the p-side current diffusion layer 34, and the n-side current diffusion layer 36.

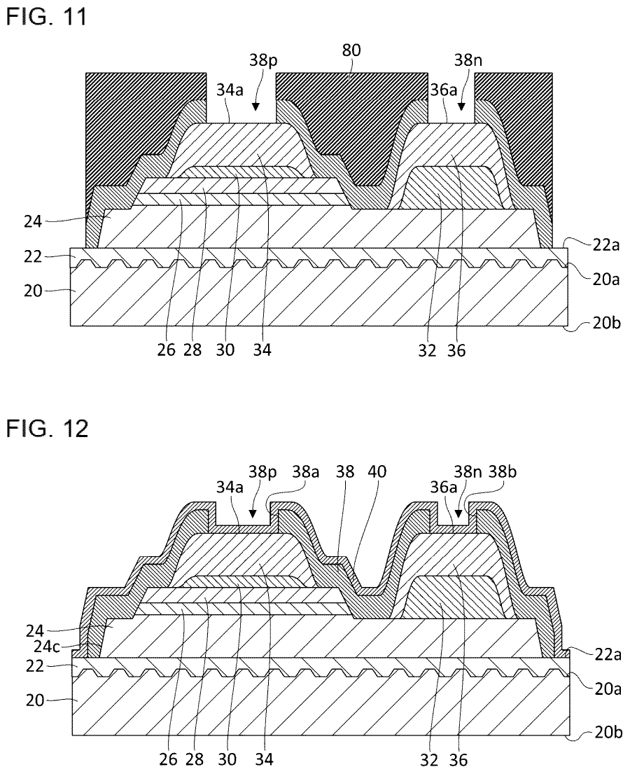

Next, as shown in FIG. 11, a mask 80 is formed on the first protective layer 38 by using, for example, a publicly known lithographic technology, and the first protective layer 38 in a region not overlapping the mask 80 is removed by dry etching or the like. The first p-side pad opening 38p in which the upper surface 34a of the p-side current diffusion layer 34 is exposed is formed by removing the first protective layer 38 on the p-side current diffusion layer 34. The first n-side pad opening 38n in which the upper surface 36a of the n-side current diffusion layer 36 is exposed is formed by removing the first protective layer 38 on the n-side current diffusion layer 36. Further, the upper surface 22a of the base layer 22 is exposed by removing an outer circumferential portion of the first protective layer 38. The mask 80 is then removed.

Subsequently, as shown in FIG. 12, the second protective layer 40 is formed to cover the entirety of the element from above. The second protective layer 40 can be made of, for example, SiNₓ, and can be formed by PECVD. The second protective layer 40 is formed to be in contact with and to cover the upper surface 22a of base layer 22 and the first protective layer 38. In the first p-side pad opening 38p, the second protective layer 40 is in contact with and covers the inner circumferential surface 38a of the first protective layer 38 that defines the first p-side pad opening 38p, and the upper surface 34a of the p-side current diffusion layer 34. In the first n-side pad opening 38n, the second protective layer 40 is in contact with and covers the inner circumferential surface 38b of the first protective layer 38 that defines the first n-side pad opening 38n, and the upper surface 36a of the n-side current diffusion layer 36.

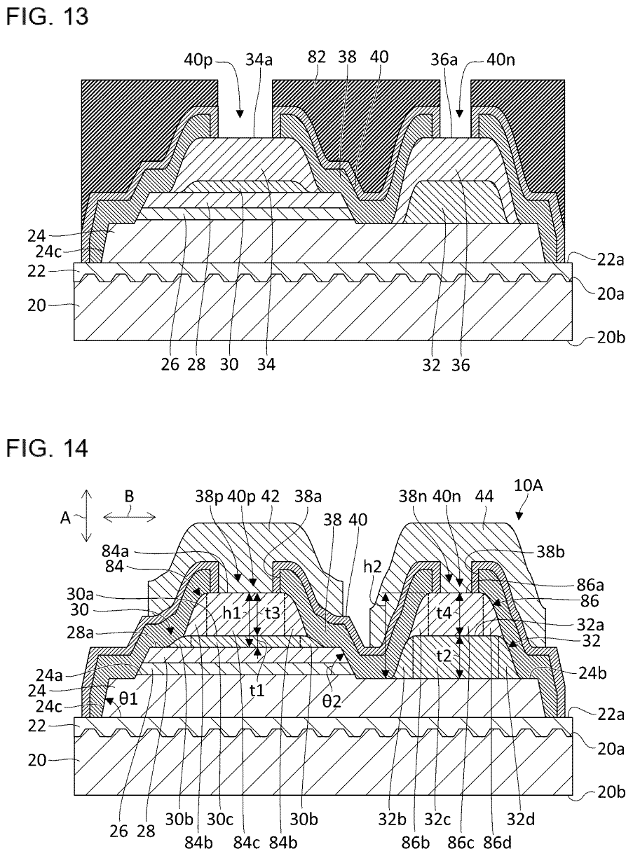

Next, as shown in FIG. 13, a mask 82 is formed on the second protective layer 40 by using, for example, a publicly known lithographic technology, and the second protective layer 40 in a region not overlapping the mask 82 is removed by dry etching or the like. The second p-side pad opening 40p in which the upper surface 34a of the p-side current diffusion layer 34 is exposed is formed by removing the second protective layer 40 on the p-side current diffusion layer 34. The second n-side pad opening 40n in which the upper surface 36a of the n-side current diffusion layer 36 is exposed is formed by removing the second protective layer 40 on the n-side current diffusion layer 36. Further, the upper surface 22a of the base layer 22 is exposed by removing the outer circumferential portion of the second protective layer 40. The mask 82 is then removed.

Subsequently, as shown in FIG. 1, the p-side pad electrode 42 connected to the p-side current diffusion layer 34 in the second p-side pad opening 40p is formed, and the n-side pad electrode 44 connected to the n-side current diffusion layer 36 in the second n-side pad opening 40n is formed. The p-side pad electrode 42 is formed to overlap the second protective layer 40 outside the second p-side pad opening 40p. The n-side pad electrode 44 is formed to overlap the second protective layer 40 outside the second n-side pad opening 40n. The p-side pad electrode 42 and the n-side pad electrode 44 can be formed concurrently but can be formed separately.

The semiconductor light-emitting element 10 shown in FIG. 1 is completed through the steps described above.

According to this embodiment, the moisture resistance of the semiconductor light-emitting element 10 can be improved by combining the first protective layer 38 made of SiO₂ and the second protective layer 40 made of SiNₓ. Further, the moisture resistance of the semiconductor light-emitting element 10 can be further improved by covering the inner circumferential surfaces 38c and 38d of the first protective layer 38 that define the first p-side pad opening 38p and the first n-side pad opening 38n with the second protective layer 40.

According to this embodiment, since the first p-side inclined portion 30b is provided at the edge of the p-side contact electrode 30, the inclination of the upper surfaces of the p-side current diffusion layer 34 covering the p-side contact electrode 30, the first protective layer 38, the second protective layer 40, and the p-side pad electrode 42 can be made gentle. Similarly, since the first inner inclined portion 32b and the first outer inclined portion 32d are provided at the edge of the n-side contact electrode 32, the inclination of the upper surfaces of the n-side current diffusion layer 36 covering the n-side contact electrode 32, the first protective layer 38, the second protective layer 40, and the n-side pad electrode 44 can be made gentle. As a result, the film thicknesses of the first protective layer 38 and the second protective layer 40 can be made uniform, and the sealing property can be improved. In addition, the film thicknesses of the p-side pad electrode 42 and the n-side pad electrode 44 can be made uniform, and a decrease in conductivity can be suppressed.

According to this embodiment, since the second p-side inclined portion 34b is provided at the edge of the p-side current diffusion layer 34, the inclination of the upper surfaces of the first protective layer 38 covering the p-side current diffusion layer 34, the second protective layer 40, and the p-side pad electrode 42 can be made gentle. Similarly, since the second inner inclined portion 36b and the second outer inclined portion 36d are provided at the edge of the n-side current diffusion layer 36, the inclination of the upper surfaces of the first protective layer 38 covering the n-side current diffusion layer 36, the second protective layer 40, and the p-side pad electrode 42 can be made gentle. As a result, the film thicknesses of the first protective layer 38 and the second protective layer 40 can be made uniform, and the sealing property can be improved. In addition, the film thicknesses of the p-side pad electrode 42 and the n-side pad electrode 44 can be made uniform, and a decrease in conductivity can be suppressed.

The semiconductor light-emitting element 10 according to this embodiment has excellent moisture resistance and so can be used without being sealed in a package. The semiconductor light-emitting element 10 can be energized for use in a condition in which the second protective layer 40 is exposed to an external environment. For example, the semiconductor light-emitting element 10 can be used in a chip on submount (CoS) mode.

### Second Embodiment

FIG. 14 is a cross sectional view schematically showing a configuration of a semiconductor light-emitting element 10A according to a second embodiment. The second embodiment is different from the first embodiment in that a formation range of a p-side current diffusion layer 84 is narrower than a formation range of a p-side contact electrode 30, and a formation range of an n-side current diffusion layer 86 is narrower than a formation range of an n-side contact electrode 32. The following description of the second embodiment highlights the difference from the first embodiment. A description of common features is omitted as appropriate.

The semiconductor light-emitting element 10A includes a substrate 20, a base layer 22, an n-type semiconductor layer 24, an active layer 26, a p-type semiconductor layer 28, the p-side contact electrode 30, the n-side contact electrode 32, the p-side current diffusion layer 84, the n-side current diffusion layer 86, a first protective layer 38, a second protective layer 40, a p-side pad electrode 42, and an n-side pad electrode 44.

The p-side current diffusion layer 84 is configured similarly to the p-side current diffusion layer 34 according to the first embodiment, but is different from the first embodiment in that the formation range of the p-side current diffusion layer 84 is narrower than the formation range of the p-side contact electrode 30. The p-side current diffusion layer 84 is provided on an upper surface 30a of the p-side contact electrode 30, and is not in contact with an upper surface 28a of the p-type semiconductor layer 28. The p-side current diffusion layer 84 includes a second p-side inclined portion 84b and a second p-side base portion 84c. The second p-side inclined portion 84b and the second p-side base portion 84c are made of the same material. The p-side current diffusion layer 84 can have a stack structure similar to that of the p-side current diffusion layer 34 according to the first embodiment. The second p-side inclined portion 84b and the second p-side base portion 84c can have the same stack structure.

The second p-side inclined portion 84b includes an overlapping portion overlapping a first p-side inclined portion 30b and a non-overlapping portion not overlapping the first p-side inclined portion 30b. The non-overlapping portion of the second p-side inclined portion 84b overlaps a first p-side base portion 30c and does not overlap the first p-side inclined portion 30b. The second p-side base portion 84c overlaps the first p-side base portion 30c and does not overlap the first p-side inclined portion 30b.

The n-side current diffusion layer 86 is configured similarly to the n-side current diffusion layer 36 according to the first embodiment, but is different from the first embodiment in that the formation range of the n-side current diffusion layer 86 is narrower than the formation range of the n-side contact electrode 32. The n-side current diffusion layer 86 is provided on an upper surface 32a of the n-side contact electrode 32, and is not in contact with a second upper surface 24b of the n-type semiconductor layer 24. The n-side current diffusion layer 86 includes a second inner inclined portion 86b, a second n-side base portion 86c, and a second outer inclined portion 86d. The second inner inclined portion 86b, the second n-side base portion 86c, and the second outer inclined portion 86d are made of the same material. The n-side current diffusion layer 86 can have a stack structure similar to that of the n-side current diffusion layer 36 according to the first embodiment. The second inner inclined portion 86b, the second n-side base portion 86c, and the second outer inclined portion 86d can have the same stack structure.

Each of the second inner inclined portion 86b and the second outer inclined portion 86d includes an overlapping portion overlapping a first inner inclined portion 32b or a first outer inclined portion 32d and a non-overlapping portion not overlapping the first inner inclined portion 32b or the first outer inclined portion 32d. The non-overlapping portion of each of the second inner inclined portion 86b and the second outer inclined portion 86d overlaps a second n-side base portion 36c. The second n-side base portion 86c overlaps a first n-side base portion 32c, and does not overlap the first inner inclined portion 32b and the first outer inclined portion 32d.

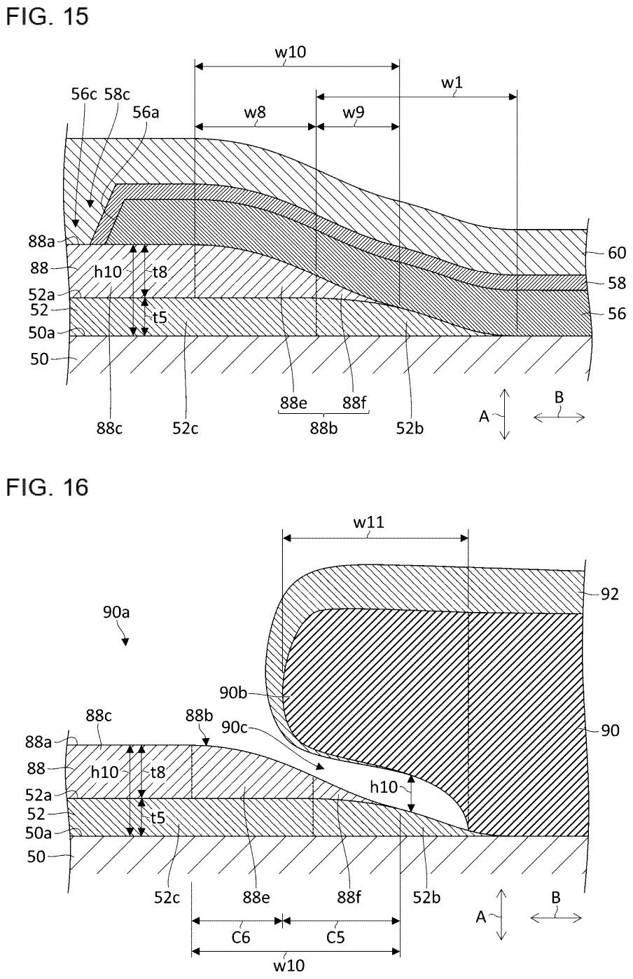

FIG. 15 is a cross sectional view schematically showing an inclined structure of a contact electrode 52 and a current diffusion layer 88 according to the second embodiment. FIG. 15 shows a structure similar to FIG. 2, and shows a structure in which the contact electrode 52, the current diffusion layer 88, a first protective layer 56, a second protective layer 58, and a pad electrode 60 are stacked on a semiconductor layer 50. The configuration of FIG. 15 is different from the configuration of FIG. 2 in that the current diffusion layer 88 is disposed inside an edge of the contact electrode 52.

The current diffusion layer 88 includes a second inclined portion 88b and a second base portion 88c. The second inclined portion 88b corresponds to the second p-side inclined portion 84b, the second inner inclined portion 86b, or the second outer inclined portion 86d described above. The second inclined portion 88b is a portion where a height h10 of an upper surface 88a decreases toward an edge of the current diffusion layer 88. The height of the upper surface 88a of the second inclined portion 88b is equal to or less than 90% of a height h3 of the upper surface 88a of the second base portion 88c. A width w10 of the second inclined portion 88b in the predetermined direction indicated by the arrow B is 10 times or more the height h10 of the upper surface 88a of the second base portion 88c. The height h10 of the upper surface 88a of the second base portion 88c is a height from an upper surface 50a of the semiconductor layer 50, and corresponds to the sum of a thickness t5 of the first base portion 52c and a thickness t8 of the second base portion 88c. The width w10 of the second inclined portion 88b is, for example, equal to or more than 5 μm and equal to or less than 20 μm. The second base portion 88c corresponds to the second p-side base portion 34c or the second n-side base portion 36c described above. The second base portion 88c is a portion where the upper surface 88a is flat such that the height h10 of the upper surface 88a of the current diffusion layer 88 is substantially constant. The height h10 of the upper surface 88a of the second base portion 88c is, for example, equal to or more than 0.2 μm and equal to or less than 2 μm. The thickness t8 of the second base portion 88c is, for example, equal to or more than 0.1 μm and equal to or less than 1 μm.

The second inclined portion 88b includes a non-overlapping portion 88e and an overlapping portion 88f. The non-overlapping portion 88e is a portion of the second inclined portion 88b not overlapping the first inclined portion 52b. In the example of FIG. 15, the non-overlapping portion 88e is a portion overlapping the first base portion 52c. The overlapping portion 88f is a portion of the second inclined portion 88b overlapping the first inclined portion 52b. In the example of FIG. 15, both the non-overlapping portion 88e and the overlapping portion 88f are formed such that the thickness t8 of the current diffusion layer 88 changes toward the edge of the current diffusion layer 88. That is, the non-overlapping portion 88e and the overlapping portion 88f are formed such that the thickness t8 of the current diffusion layer 88 decreases toward the edge of the current diffusion layer 88.

A width w8 of the non-overlapping portion 88e in the predetermined direction indicated by the arrow B is equal to or more than half of a width w1 of the first inclined portion 52b, and preferably equal to or more than 60%. The width w8 of the non-overlapping portion 88e is, for example, equal to or more than 2 μm and equal to or less than 10 μm. A width w9 of the overlapping portion 88f in the predetermined direction indicated by the arrow B is less than half of the width w1 of the first inclined portion 52b, and preferably equal to or less than 40%. The width w9 of the overlapping portion 88f is, for example, equal to or more than 1 μm and equal to or less than 5 μm.

In the configuration of FIG. 15, the inclination of the upper surface 88a of the current diffusion layer 88 tends to increase at the position of the overlapping portion 88f. This is because the inclination of the upper surface 88a of the overlapping portion 88f corresponds to the sum of the contribution of the inclination of the first inclined portion 52b whose thickness t5 changes and the contribution of the inclination of the second inclined portion 88b whose thickness t8 changes. In the configuration of FIG. 15, the width w9 of the overlapping portion 88f where the inclination of the upper surface 88a tends to increase can be relatively decreased by relatively decreasing the width w9 of the overlapping portion 88f. As a result, the inclinations of the first protective layer 56, the second protective layer 58, and the pad electrode 60 stacked on the upper surface 88a of the current diffusion layer 88 can be decreased, and the thicknesses of the first protective layer 56, the second protective layer 58, and the pad electrode 60 can be made uniform. As a result, it is possible to prevent the first protective layer 56 and the second protective layer 58 from being locally decreased in thickness to deteriorate a covering property. In addition, it is possible to prevent a decrease in conductivity due to a local decrease in thickness of the pad electrode 60. As a result, the reliability of the semiconductor light-emitting element 10 can be improved.

In addition, the inclination of an upper surface 52a of the first inclined portion 52b can be decreased by setting the width w1 of the first inclined portion 52b to 10 times or more the thickness t5 of the first base portion 52c. Similarly, the inclination of the upper surface 88a of the second inclined portion 88b can be decreased by setting the width w10 of the second inclined portion 88b to 10 times or more the height h10 of the upper surface 88a of the second base portion 88c. As a result, the inclinations of the first protective layer 56, the second protective layer 58, and the pad electrode 60 stacked on the upper surface 88a of the current diffusion layer 88 can be decreased, and the thicknesses of the first protective layer 56, the second protective layer 58, and the pad electrode 60 can be made uniform. As a result, it is possible to prevent the first protective layer 56 and the second protective layer 58 from being locally decreased in thickness to deteriorate a covering property. In addition, it is possible to prevent a decrease in conductivity due to a local decrease in thickness of the pad electrode 60. As a result, the reliability of the semiconductor light-emitting element 10 can be improved.

FIG. 16 is a cross sectional view schematically showing a step of forming the current diffusion layer 88 according to the second embodiment. FIG. 16 shows a step after the step of forming the contact electrode 52 in FIG. 3. First, a second resist 90 is formed on the semiconductor layer 50 on which the contact electrode 52 is formed. The second resist 90 can be formed using a lithographic technology. The second resist 90 has a second opening 90a positioned in a region in which the current diffusion layer 88 is to be formed, and is formed in a region excluding the second opening 90a. The second opening 90a of the second resist 90 has a so-called undercut shape. The second resist 90 has an eaves portion 90b protruding toward the second opening 90a, and an undercut-shaped gap 90c is provided between the upper surface 52a of the contact electrode 52 and the eaves portion 90b. The height h10 of the undercut-shaped gap 90c is equal to or more than 0.1 μm and equal to or less than 1 μm. A width w11 of the undercut-shaped gap 90c in the predetermined direction indicated by the arrow B is equal to or more than 5 μm and equal to or less than 10 μm. The eaves portion 90b of the second resist 90 is formed at a position overlapping the contact electrode 52. The eaves portion 90b of the second resist 90 is formed, for example, at a position overlapping the first base portion 52c of the contact electrode 52.

Next, a stack structure 92 is deposited on the second resist 90 to form the current diffusion layer 88 in the second opening 90a. The stack structure 92 has, for example, a structure in which Ti/TiN/Ti/Rh/TiN are sequentially stacked. The stack structure 92 can be deposited using, for example, a sputtering method. By using the sputtering method, sputtered particles having an angular distribution (for example, +10 degrees or more) can be incident on the upper surface 50a of the semiconductor layer 50. As a result, the sputtered particles can effectively reach the back side of the undercut-shaped gap 90c, and the width w10 of the second inclined portion 88b of the current diffusion layer 88 can be increased. The second inclined portion 88b of the current diffusion layer 88 is formed over a region C5 overlapping the second resist 90 (eaves portion 90b) and a region C6 not overlapping the second resist 90. The non-overlapping portion 88e of the second inclined portion 88b is formed in the region C6 not overlapping the second resist 90 (eaves portion 90b). The non-overlapping portion 88e of the second inclined portion 88b may be formed in the region C5 overlapping the second resist 90 (eaves portion 90b). The overlapping portion 88f of the second inclined portion 88b is formed, for example, in the region C5 overlapping the second resist 90. After the current diffusion layer 88 is formed, the second resist 90 is removed.

A description will now be given of a method of manufacturing the semiconductor light-emitting element 10A according to the second embodiment. The semiconductor light-emitting element 10A according to the second embodiment can be formed by the same steps as those of the first embodiment shown in FIGS. 5 to 13.

In the second embodiment, a second resist similar to the second resist 90 shown in FIG. 16 is used in a step of forming the p-side current diffusion layer 34 and the n-side current diffusion layer 36 shown in FIG. 8. That is, the p-side current diffusion layer 84 and the n-side current diffusion layer 86 can be formed by using the second resist formed such that the eaves portion of the second resist overlaps each of the p-side contact electrode 30 and the n-side contact electrode 32.

This embodiment provides the same advantage as the first embodiment.

In still another embodiment, the p-side current diffusion layer 34 according to the first embodiment and the n-side current diffusion layer 86 according to the second embodiment may be combined. That is, the semiconductor light-emitting element may include the p-side current diffusion layer 34 formed in a range wider than the formation range of the p-side contact electrode 30, and the n-side current diffusion layer 86 formed in a range narrower than the formation range of the n-side contact electrode 32.

In still another embodiment, the p-side current diffusion layer 84 according to the second embodiment and the n-side current diffusion layer 36 according to the first embodiment may be combined. That is, the semiconductor light-emitting element may include the p-side current diffusion layer 84 formed in a range narrower than the formation range of the p-side contact electrode 30, and the n-side current diffusion layer 36 formed in a range wider than the formation range of the n-side contact electrode 32.

Described above is an explanation based on the embodiments. The embodiments are intended to be illustrative only and it will be understood by those skilled in the art that various design changes are possible and various modifications are possible and that such modifications are also within the scope of the present invention.

Some modes of the present invention will be described.

A first aspect of the present invention is a semiconductor light-emitting element including: an n-type semiconductor layer; an active layer provided on a first upper surface of the n-type semiconductor layer; a p-type semiconductor layer provided on the active layer; a contact electrode in contact with a second upper surface different from the first upper surface of the n-type semiconductor layer or in contact with an upper surface of the p-type semiconductor layer; a protective layer covering the n-type semiconductor layer, the active layer, the p-type semiconductor layer, and the contact electrode and made of a dielectric material; and a pad electrode provided on the protective layer, in which the contact electrode includes a first inclined portion in which an upper surface of the contact electrode is inclined such that a thickness of the contact electrode decreases toward an edge of the contact electrode, and a width of the first inclined portion in a direction in which the edge of the contact electrode extends and a predetermined direction orthogonal to a thickness direction of the contact electrode is 10 times or more a thickness of a portion of the contact electrode that is different from the first inclined portion. According to the first aspect, since the first inclined portion is provided at the edge of the contact electrode, and the width of the first inclined portion is 10 times or more the thickness of the contact electrode, the inclination of the upper surface of the first inclined portion can be made gentle. Therefore, the film thickness of the protective layer covering the first inclined portion can be made uniform, and the sealing property of the protective layer can be enhanced. As a result, the reliability of the semiconductor light-emitting element can be improved.

A second aspect of the present invention is the semiconductor light-emitting element according to the first aspect, in which the thickness of the portion of the contact electrode that is different from the first inclined portion is equal to or more than 0.1 μm and equal to or less than 1 μm. According to the second aspect, a suitable contact resistance can be achieved at the portion different from the first inclined portion by setting the thickness of the contact electrode to 0.1 μm or more. In addition, it is possible to prevent the width of the first inclined portion from becoming excessively large and to prevent the width of the portion different from the first inclined portion from decreasing by setting the thickness of the contact electrode to 1 μm or less. Thus, a suitable contact resistance can be achieved at the portion different from the first inclined portion.

A third aspect of the present invention is the semiconductor light-emitting element according to the first or second aspect, in which the width of the first inclined portion in the predetermined direction is equal to or more than 5 μm and equal to or less than 10 μm. According to the third aspect, the inclination of the upper surface of the first inclined portion can be made gentle by setting the width of the first inclined portion to 5 μm or more. In addition, it is possible to prevent the width of a portion different from the first inclined portion from decreasing by setting the width of the first inclined portion to 10 μm or less.

A fourth aspect of the present invention is the semiconductor light-emitting element according to any one of the first to third aspects, further including a current diffusion layer provided on the contact electrode, covered with the protective layer, and having a stack structure in which a TiN layer, a metal layer, and a TiN layer are sequentially stacked, in which the current diffusion layer includes a second inclined portion inclined such that a height of an upper surface of the current diffusion layer decreases toward an edge of the current diffusion layer, and a width of the second inclined portion in the predetermined direction is 10 times or more a thickness of a portion of the current diffusion layer that is different from the second inclined portion. According to the fourth aspect, since the second inclined portion is provided at the edge of the current diffusion layer and the width of the second inclined portion is 10 times or more the thickness of the current diffusion layer, the inclination of the upper surface of the second inclined portion can be made gentle. Therefore, the film thickness of the protective layer covering the second inclined portion can be made uniform, and the sealing property of the protective layer can be enhanced. As a result, the reliability of the semiconductor light-emitting element can be improved.

A fifth aspect of the present invention is the semiconductor light-emitting element according to the fourth aspect, in which a sum of the thickness of the portion of the contact electrode that is different from the first inclined portion and the thickness of the portion of the current diffusion layer that is different from the second inclined portion is equal to or more than 0.2 μm and equal to or less than 2 μm. According to the fifth aspect, it is possible to achieve a suitable contact resistance and current diffusion function at the portion different from the first inclined portion and the second inclined portion by setting the sum of the thicknesses of the contact electrode and the current diffusion layer to 0.2 μm or more. In addition, it is possible to prevent the width of the second inclined portion from becoming excessively large and to prevent the width of the portion different from the second inclined portion from decreasing by setting the sum of the thicknesses of the contact electrode and the current diffusion layer to 2 μm or less. As a result, a suitable current diffusion function can be achieved at the portion different from the second inclined portion.

A sixth aspect of the present invention is the semiconductor light-emitting element according to the fourth or fifth aspect, in which the second inclined portion includes an overlapping portion overlapping the first inclined portion and a non-overlapping portion not overlapping the first inclined portion, and a width of the non-overlapping portion of the second inclined portion in the predetermined direction is equal to or more than half of the width of the first inclined portion in the predetermined direction. According to the sixth aspect, the width of the overlapping portion where the inclination tends to increase on the upper surface of the current diffusion layer can be decreased by increasing the width of the non-overlapping portion of the second inclined portion. As a result, the film thickness of the protective layer covering the second inclined portion can be made uniform, and the sealing property of the protective layer can be enhanced.

A seventh aspect of the present invention is the semiconductor light-emitting element according to the sixth aspect, in which the non-overlapping portion does not overlap the contact electrode. According to the seventh aspect, since the current diffusion layer is provided outside the formation range of the contact electrode, the entire contact electrode can be covered with the current diffusion layer. As a result, the contact electrode can be protected by the current diffusion layer, and a more suitable current diffusion function can be achieved.

An eighth aspect of the present invention is the semiconductor light-emitting element according to the sixth aspect, in which the non-overlapping portion overlaps the portion of the contact electrode that is different from the first inclined portion. According to the eighth aspect, since the contact electrode is provided outside the formation range of the current diffusion layer, the area of the contact electrode can be maximized. As a result, a more suitable contact resistance and current diffusion function can be achieved.

A ninth aspect of the present invention is the semiconductor light-emitting element according to any one of the first to eighth aspects, in which the contact electrode includes an n-side contact electrode in contact with the second upper surface of the n-type semiconductor layer, the n-side contact electrode includes a first inner inclined portion in which an upper surface of the n-side contact electrode is inclined such that a thickness of the n-side contact electrode decreases toward the active layer, and a first outer inclined portion in which the upper surface of the n-side contact electrode is inclined such that the thickness of the n-side contact electrode decreases as a distance from the active layer increases, and a width of each of the first inner inclined portion and the first outer inclined portion in the predetermined direction is 10 times or more a thickness of a portion of the n-side contact electrode that is different from the first inner inclined portion and the first outer inclined portion. According to the ninth aspect, since the width of each of the first inner inclined portion and the first outer inclined portion is 10 times or more the thickness of the n-side contact electrode, the inclination of the upper surface of each of the first inner inclined portion and the first outer inclined portion can be made gentle. As a result, the film thickness of the protective layer covering the first inner inclined portion and the first outer inclined portion can be made uniform, and the sealing property of the protective layer can be enhanced. As a result, the reliability of the semiconductor light-emitting element can be improved.

A tenth aspect of the present invention is the semiconductor light-emitting element according to the ninth aspect, further including an n-side current diffusion layer provided on the n-side contact electrode, covered with the protective layer, and having a stack structure in which a TiN layer, a metal layer, and a TiN layer are sequentially stacked, in which the n-side current diffusion layer includes a second inner inclined portion in which an upper surface of the n-side current diffusion layer is inclined such that a height of the n-side current diffusion layer decreases toward the active layer, and a second outer inclined portion in which the upper surface of the n-side current diffusion layer is inclined such that the height of the n-side current diffusion layer decreases as a distance from the active layer increases, and a width of each of the second inner inclined portion and the second outer inclined portion in the predetermined direction is 10 times or more a thickness of a portion of the n-side current diffusion layer that is different from the second inner inclined portion and the second outer inclined portion. According to the tenth aspect, since the width of each of the second inner inclined portion and the second outer inclined portion is 10 times or more the thickness of the n-side current diffusion layer, the inclination of the upper surface of each of the second inner inclined portion and the second outer inclined portion can be made gentle. As a result, the film thickness of the protective layer covering the second inner inclined portion and the second outer inclined portion can be made uniform, and the sealing property of the protective layer can be enhanced.

An eleventh aspect of the present invention is the semiconductor light-emitting element according to any one of the first to tenth aspects, in which the contact electrode includes a p-side contact electrode in contact with the upper surface of the p-type semiconductor layer, the p-side contact electrode includes a first p-side inclined portion in which an upper surface of the p-side contact electrode is inclined such that a thickness of the p-side contact electrode decreases toward an edge of the p-side contact electrode, and a width of the first p-side inclined portion in the predetermined direction is 10 times or more a thickness of a portion of the p-side contact electrode that is different from the first p-side inclined portion. According to the eleventh aspect, since the width of the first p-side inclined portion is 10 times or more the thickness of the p-side contact electrode, the inclination of the upper surface of the first p-side inclined portion can be made gentle. Accordingly, the thickness of the protective layer covering the first p-side inclined portion can be made uniform, and the sealing property of the protective layer can be enhanced.

A twelfth aspect of the present invention is the semiconductor light-emitting element according to the eleventh aspect, further including a p-side current diffusion layer provided on the p-side contact electrode, covered with the protective layer, and having a stack structure in which a TiN layer, a metal layer, and a TiN layer are sequentially stacked, in which the p-side current diffusion layer includes a second p-side inclined portion in which an upper surface of the p-side current diffusion layer is inclined such that a height of the p-side current diffusion layer decreases toward an edge of the p-side current diffusion layer, and a width of the second p-side inclined portion in the predetermined direction is 10 times or more a thickness of a portion of the p-side current diffusion layer that is different from the second p-side inclined portion. According to the twelfth aspect, since the width of the second p-side inclined portion is 10 times or more the thickness of the p-side current diffusion layer, the inclination of the upper surface of the second p-side inclined portion can be made gentle. Accordingly, the thickness of the protective layer covering the second p-side inclined portion can be made uniform, and the sealing property of the protective layer can be enhanced.

A thirteenth aspect of the present invention is a method of manufacturing a semiconductor light-emitting element, the method including: forming an active layer on an n-type semiconductor layer; forming a p-type semiconductor layer on the active layer; partially removing each of the p-type semiconductor layer and the active layer to expose an upper surface of the n-type semiconductor layer; forming an n-side contact electrode in contact with the upper surface of the n-type semiconductor layer; forming a p-side contact electrode in contact with an upper surface of the p-type semiconductor layer; forming a protective layer made of a dielectric material and covering the n-type semiconductor layer, the active layer, the p-type semiconductor layer, the n-side contact electrode, and the p-side contact electrode; partially removing the protective layer to form an n-side opening and a p-side opening; forming an n-side pad electrode overlapping the protective layer to close the n-side opening; and forming a p-side pad electrode overlapping the protective layer to close the p-side opening, in which at least one of the forming of the n-side contact electrode or the forming of the p-side contact electrode includes: forming a first resist having a first opening having an undercut shape; depositing an electrode layer in the first opening by using the first resist as a mask; and peeling and removing the first resist, a width of the undercut shape of the first resist in a direction in which an edge of the first opening of the first resist extends and a predetermined direction orthogonal to a thickness direction of the first resist is equal to or more than 5 μm and equal to or less than 10 μm, and a height of the undercut shape of the first resist is equal to or less than 1 μm. According to the thirteenth aspect, the inclination of the upper surface of the electrode layer formed in the first opening can be made gentle by setting the width of the undercut shape of the first resist to 5 μm or more and 10 μm or less and setting the height of the undercut shape of the first resist to 1 μm or less. As a result, the film thickness of the protective layer covering the electrode layer can be made uniform, and the sealing property of the protective layer can be enhanced.

A fourteenth aspect of the present invention is the method according to the thirteenth aspect, in which the depositing of the electrode layer includes depositing sputtered particles passing through the first opening of the first resist. According to the fourteenth aspect, by depositing the electrode layer using the sputtered particles, the sputtered particles can reach the back side of the undercut-shaped opening, and the inclination of the upper surface of the electrode layer formed in the first opening can be made gentle.

A fifteenth aspect of the present invention is the method according to the thirteenth or fourteenth aspect, further including: forming an n-side current diffusion layer on the n-side contact electrode, the n-side current diffusion layer having a stack structure in which a TiN layer, a metal layer, and a TiN layer are sequentially stacked; and forming a p-side current diffusion layer on the p-side contact electrode, the p-side current diffusion layer having a stack structure in which a TiN layer, a metal layer, and a TiN layer are sequentially stacked, in which the protective layer is formed to further cover the n-side current diffusion layer and the p-side current diffusion layer, at least one of the forming of the n-side current diffusion layer or the forming of the p-side current diffusion layer includes: forming a second resist having a second opening having an undercut shape; depositing the stack structure in the second opening by using the second resist as a mask; and peeling and removing the second resist, a width of the undercut shape of the second resist in a direction in which an edge of the second opening of the second resist extends and in a predetermined direction orthogonal to a thickness direction of the second resist is equal to or more than 5 μm and equal to or less than 10 μm, and a height of the undercut shape of the second resist is equal to or less than 1 μm. According to the fifteenth aspect, by setting the width of the undercut shape of the second resist to 5 μm or more and 10 μm or less and setting the height of the undercut shape of the second resist to 1 μm or less, the inclination of the upper surface of the current diffusion layer formed in the second opening can be made gentle. As a result, the film thickness of the protective layer covering the current diffusion layer can be made uniform, and the sealing property of the protective layer can be enhanced.

A sixteenth aspect of the present invention is the method according to the fifteenth aspect, in which the depositing of the stack structure includes depositing sputtered particles passing through the second opening of the second resist. According to the sixteenth aspect, by depositing the current diffusion layer using the sputtered particles, the sputtered particles can reach the back side of the undercut-shaped opening, and the inclination of the upper surface of the current diffusion layer formed in the second opening can be made gentle.

What is claimed is:

1. A semiconductor light-emitting element comprising:
an n-type semiconductor layer;
an active layer provided on a first upper surface of the n-type semiconductor layer;
a p-type semiconductor layer provided on the active layer;
a contact electrode in contact with a second upper surface different from the first upper surface of the n-type semiconductor layer or in contact with an upper surface of the p-type semiconductor layer;
a protective layer covering the n-type semiconductor layer, the active layer, the p-type semiconductor layer, and the contact electrode and made of a dielectric material; and
a pad electrode provided on the protective layer,
wherein the contact electrode includes a first inclined portion in which an upper surface of the contact electrode is inclined such that a thickness of the contact electrode decreases toward an edge of the contact electrode, and
wherein a width of the first inclined portion in a direction in which the edge of the contact electrode extends and a predetermined direction orthogonal to a thickness direction of the contact electrode is 10 times or more a thickness of a portion of the contact electrode that is different from the first inclined portion.

2. The semiconductor light-emitting element according to claim 1, wherein the thickness of the portion of the contact electrode that is different from the first inclined portion is equal to or more than 0.1 μm and equal to or less than 1 μm.

3. The semiconductor light-emitting element according to claim 1, wherein the width of the first inclined portion in the predetermined direction is equal to or more than 5 μm and equal to or less than 10 μm.

4. The semiconductor light-emitting element according to claim 1, further comprising a current diffusion layer provided on the contact electrode, covered with the protective layer, and having a stack structure in which a TiN layer, a metal layer, and a TiN layer are sequentially stacked,
wherein the current diffusion layer includes a second inclined portion inclined such that a height of an upper surface of the current diffusion layer decreases toward an edge of the current diffusion layer, and
wherein a width of the second inclined portion in the predetermined direction is 10 times or more a thickness of a portion of the current diffusion layer that is different from the second inclined portion.

5. The semiconductor light-emitting element according to claim 4, wherein a sum of the thickness of the portion of the contact electrode that is different from the first inclined portion and the thickness of the portion of the current diffusion layer that is different from the second inclined portion is equal to or more than 0.2 μm and equal to or less than 2 μm.

6. The semiconductor light-emitting element according to claim 4, wherein the second inclined portion includes an overlapping portion overlapping the first inclined portion and a non-overlapping portion not overlapping the first inclined portion, and
wherein a width of the non-overlapping portion of the second inclined portion in the predetermined direction is equal to or more than half of the width of the first inclined portion in the predetermined direction.

7. The semiconductor light-emitting element according to claim 6, wherein the non-overlapping portion does not overlap the contact electrode.

8. The semiconductor light-emitting element according to claim 6, wherein the non-overlapping portion overlaps the portion of the contact electrode that is different from the first inclined portion.

9. The semiconductor light-emitting element according to claim 1, wherein the contact electrode includes an n-side contact electrode in contact with the second upper surface of the n-type semiconductor layer,
wherein the n-side contact electrode includes a first inner inclined portion in which an upper surface of the n-side contact electrode is inclined such that a thickness of the n-side contact electrode decreases toward the active layer, and a first outer inclined portion in which the upper surface of the n-side contact electrode is inclined such that the thickness of the n-side contact electrode decreases as a distance from the active layer increases, and
wherein a width of each of the first inner inclined portion and the first outer inclined portion in the predetermined direction is 10 times or more a thickness of a portion of the n-side contact electrode that is different from the first inner inclined portion and the first outer inclined portion.

10. The semiconductor light-emitting element according to claim 9, further comprising an n-side current diffusion layer provided on the n-side contact electrode, covered with the protective layer, and having a stack structure in which a TiN layer, a metal layer, and a TiN layer are sequentially stacked,
wherein the n-side current diffusion layer includes a second inner inclined portion in which an upper surface of the n-side current diffusion layer is inclined such that a height of the n-side current diffusion layer decreases toward the active layer, and a second outer inclined portion in which the upper surface of the n-side current diffusion layer is inclined such that the height of the n-side current diffusion layer decreases as a distance from the active layer increases, and
wherein a width of each of the second inner inclined portion and the second outer inclined portion in the predetermined direction is 10 times or more a thickness of a portion of the n-side current diffusion layer that is different from the second inner inclined portion and the second outer inclined portion.

11. The semiconductor light-emitting element according to claim 1, wherein the contact electrode includes a p-side contact electrode in contact with the upper surface of the p-type semiconductor layer,
wherein the p-side contact electrode includes a first p-side inclined portion in which an upper surface of the p-side contact electrode is inclined such that a thickness of the p-side contact electrode decreases toward an edge of the p-side contact electrode, and
wherein a width of the first p-side inclined portion in the predetermined direction is 10 times or more a thickness of a portion of the p-side contact electrode that is different from the first p-side inclined portion.

12. The semiconductor light-emitting element according to claim 11, further comprising a p-side current diffusion layer provided on the p-side contact electrode, covered with the protective layer, and having a stack structure in which a TiN layer, a metal layer, and a TiN layer are sequentially stacked,
wherein the p-side current diffusion layer includes a second p-side inclined portion in which an upper surface of the p-side current diffusion layer is inclined such that a height of the p-side current diffusion layer decreases toward an edge of the p-side current diffusion layer, and
wherein a width of the second p-side inclined portion in the predetermined direction is 10 times or more a thickness of a portion of the p-side current diffusion layer that is different from the second p-side inclined portion.

13. A method of manufacturing a semiconductor light-emitting element, the method comprising:
forming an active layer on an n-type semiconductor layer;
forming a p-type semiconductor layer on the active layer;
partially removing each of the p-type semiconductor layer and the active layer to expose an upper surface of the n-type semiconductor layer;
forming an n-side contact electrode in contact with the upper surface of the n-type semiconductor layer;
forming a p-side contact electrode in contact with an upper surface of the p-type semiconductor layer;
forming a protective layer made of a dielectric material and covering the n-type semiconductor layer, the active layer, the p-type semiconductor layer, the n-side contact electrode, and the p-side contact electrode;
partially removing the protective layer to form an n-side opening and a p-side opening;
forming an n-side pad electrode overlapping the protective layer to close the n-side opening; and
forming a p-side pad electrode overlapping the protective layer to close the p-side opening,
wherein at least one of the forming of the n-side contact electrode or the forming of the p-side contact electrode includes:
forming a first resist having a first opening having an undercut shape;
depositing an electrode layer in the first opening by using the first resist as a mask; and
peeling and removing the first resist,
wherein a width of the undercut shape of the first resist in a direction in which an edge of the first opening of the first resist extends and a predetermined direction orthogonal to a thickness direction of the first resist is equal to or more than 5 μm and equal to or less than 10 μm, and
wherein a height of the undercut shape of the first resist is equal to or less than 1 μm.

14. The method according to claim 13, wherein the depositing of the electrode layer includes depositing sputtered particles passing through the first opening of the first resist.

15. The method according to claim 13, further comprising:
forming an n-side current diffusion layer on the n-side contact electrode, the n-side current diffusion layer having a stack structure in which a TiN layer, a metal layer, and a TiN layer are sequentially stacked; and
forming a p-side current diffusion layer on the p-side contact electrode, the p-side current diffusion layer having a stack structure in which a TiN layer, a metal layer, and a TiN layer are sequentially stacked,
wherein the protective layer is formed to further cover the n-side current diffusion layer and the p-side current diffusion layer,
wherein at least one of the forming of the n-side current diffusion layer or the forming of the p-side current diffusion layer includes:
forming a second resist having a second opening having an undercut shape;
depositing the stack structure in the second opening by using the second resist as a mask; and
peeling and removing the second resist,
wherein a width of the undercut shape of the second resist in a direction in which an edge of the second opening of the second resist extends and in a predetermined direction orthogonal to a thickness direction of the second resist is equal to or more than 5 μm and equal to or less than 10 μm, and
wherein a height of the undercut shape of the second resist is equal to or less than 1 μm.

16. The method according to claim 15, wherein the depositing of the stack structure includes depositing sputtered particles passing through the second opening of the second resist.
